(19) United States
(12) Patent Application Publication
(10) Pub. No.: US 2025/0093772 A1
(43) Pub. Date: Mar. 20, 2025

(54) PHOTORESIST COMPOSITIONS AND METHODS OF FORMING PATTERNS USING A PHOTORESIST COMPOSITION

(71) Applicant: Samsung Electronics Co., Ltd., Suwon-si (KR)

(72) Inventors: Chawon Koh, Suwon-si (KR); Hyo Jae Yoon, Seoul (KR); Tsunehiro Nishi, Suwon-si (KR); Gayeong Lim, Seoul (KR)

(73) Assignee: Korea University Research and Business Foundation, Seoul (KR)

(21) Appl. No.: 18/777,777

(22) Filed: Jul. 19, 2024

(30) Foreign Application Priority Data
Sep. 18, 2023 (KR) 10-2023-0124247

(51) Int. Cl. G03F 7/004; C07F 7/22

(52) U.S. Cl. CPC G03F 7/0042; C07F 7/2224

(57) ABSTRACT

The present invention relates to PHOTORESIST COMPOSITIONS AND METHODS OF FORMING PATTERNS USING A PHOTORESIST COMPOSITION. Disclosed is a photoresist composition including an organometallic compound including a ring including a metal, a first heteroatom coordinated to the metal, and a second heteroatom covalently bonded to the metal, and an aromatic ring substituted or fused to the ring; and a solvent.

### CROSS-REFERENCE TO RELATED APPLICATION

This application claims priority to Korean Patent Application No. 10-2023-0124247, filed on Sep. 18, 2023, in the Korean Intellectual Property Office, the entire contents of which are incorporated herein by reference.

### FIELD

This disclosure relates to a photoresist composition and a method of forming patterns using the same. More specifically, it relates to a photoresist composition for extreme ultraviolet lithography including multinuclear metal-based supramolecules and a method of forming patterns using the same.

### BACKGROUND

EUV (extreme ultraviolet) lithography is one technology for manufacturing a next generation semiconductor device. EUV lithography is a pattern-forming technology using an EUV ray having a wavelength of about 13.5 nm as an exposure light source. According to EUV lithography, an extremely small pattern (e.g., less than or equal to about 20 nm) may be formed in an exposure process during manufacture of a semiconductor device.

EUV lithography is realized through development of compatible photoresists which can be performed at a spatial resolution of less than or equal to about 16 nm. Currently, efforts to satisfy insufficient specifications of traditional chemically amplified (CA) photoresists such as resolution, photospeed, and feature roughness (or referred to be line edge roughness (LER)) for the next generation device are being made.

An intrinsic image blur due to an acid catalyzed reaction in these polymer-type photoresists limits resolution in small feature sizes, which is well known in electron beam (e-beam) lithography. CA photoresists are designed for high sensitivity, but since their typical elemental makeups reduce light absorbance of the photoresists at a wavelength of about 13.5 nm, and thus decrease their sensitivity, the CA photoresists may have more difficulties under an EUV exposure.

In addition, the CA photoresists may have difficulties in small feature sizes due to roughness issues, and line edge roughness (LER) of the CA photoresists experimentally is increased, as photospeed is decreased, partially due to the essence of acid catalytic processes.

Due to the drawbacks and problems of CA photoresists, there are needs in the semiconductor industry for new types of high-performance photoresists.

### SUMMARY

One aspect of the present disclosure is to provide a photoresist composition capable of forming (e.g., configured to form and/or that can form) patterns with a size of 20 nm or less using extreme ultraviolet (EUV), achieve high resolution and low line edge roughness (LER) with just a single exposure process, reduce wafer-to-wafer critical dimension (CD) deviation due to the photoresist composition having excellent moisture stability and environmental stability, and/or reduce an occurrence of defects by reducing photoresist residues in non-exposed regions.

Another aspect of the present disclosure provides a method of forming patterns using a photoresist composition.

A photoresist composition according to one aspect includes an organometallic compound including a ring including a metal, a first heteroatom coordinated to the metal and a second heteroatom covalently bonded to the metal, and an aromatic ring substituted or fused to the ring; and a solvent.

A photoresist composition according to another aspect includes an organometallic compound represented by Chemical Formula 1; and a solvent.

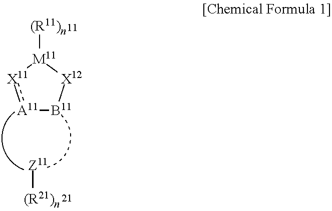

In Chemical Formula 1, M¹¹ is a metal including Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe, X¹¹ and X² are each independently O, S, or NR′, A¹¹ and B¹¹ are each independently a linking group including a single bond, a double bond, an alkylene group, O, S, NR′, NHC(═O), SO, SO₂, CO, O—CO—O, C(═O)O, OCO, or any combination thereof, Z¹¹ is an aromatic ring substituted for A¹¹, or Z¹¹ is a linking group including a single bond, double bond, alkylene group, O, S, NR′, NHC(═O), SO, SO₂, CO, O—CO—O, C(═O)O, OCO, or any combination thereof that is fused to A¹¹ and B¹¹ to form an aromatic ring, R¹¹ and R²¹ are each independently a substituent including a hydrogen, a hydroxy group, a halogen, an alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, R¹¹ is a solvent coordinated to M¹¹, or R¹¹ and R²¹ are each independently a linking group including a single bond, a double bond, an alkylene group, O, S, NR′, NHC(═O), SO, SO₂, CO, O—CO—O, C(═O)O, OCO, or any combination thereof, R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, n¹¹ is the number of substitutable (bondable) positions of M¹¹, and n²¹ is the number of substitutable positions of the aromatic ring.

A method of forming patterns according to another aspect includes forming a film to be etched on a substrate; forming a photoresist film by applying the aforementioned photoresist composition on the film to be etched; patterning the photoresist film to form a photoresist pattern; and etching the film to be etched using the photoresist pattern as an etching mask.

According to example embodiments, the photoresist composition is capable of forming (e.g., configured to form and/or that can form) patterns with a size of 20 nm or less using extreme ultraviolet rays, can achieve high resolution and low line edge roughness (e.g., of about 1.2 nm or less) with just a single exposure process, can reduce a critical dimension deviation between wafers due to excellent moisture stability and environmental stability, and can reduce an occurrence of defects by reducing photoresist residues in non-exposed regions.

### BRIEF DESCRIPTION OF THE DRAWINGS

Embodiments will be more clearly understood from the following detailed description taken in conjunction with the accompanying drawings:

FIGS. 1 to 5 are cross-sectional views illustrating aspects of intermediate steps of the method of forming patterns.

FIGS. 6 to 8 show the NMR spectroscopy spectrum results of an exemplary organometallic compound prepared in Synthesis Example 1, showing proton NMR, ¹³C NMR, and ¹¹⁹Sn NMR results, respectively.

FIG. 9 is a graph showing the results of thermogravimetric analysis of the organometallic compound prepared in Synthesis Example 1.

FIGS. 10A-10B are scanning electron microscope (SEM) photographs before (10A) and after (10B) exposure in a photoreactivity test for electron beam.

FIGS. 11A-11I are scanning electron microscope (SEM) photographs of the after develop inspection (ADI) results of the photoreactivity test for EUV.

### DETAILED DESCRIPTION

Hereinafter, various embodiments of the present disclosure will be described in detail with reference to the accompanying drawings so that those of ordinary skill in the art may easily implement the present disclosure. The present disclosure may be implemented in various different forms and is not limited to the embodiments described herein.

The drawings and description are to be regarded as illustrative in nature and not restrictive. Like reference numerals designate like elements throughout the specification.

Further, in the drawings, size and thickness of each element are arbitrarily represented for better understanding and ease of description, but the present disclosure is not limited thereto. In the drawings, the thickness of layers, films, panels, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

As used herein, when specific definition is not otherwise provided, “substituted” refers to replacement of a hydrogen atom by deuterium, a halogen, a hydroxy group, a cyano group, a nitro group, —NRR′ (wherein R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, C1 to C10 alkylsilyl group, a C3 to C30 cycloalkyl group, a C6 to C30 aryl group, C1 to C20 alkoxy group, or any combination thereof. “Unsubstituted” means that a hydrogen atom remains without being substituted with another substituent.

As used herein, when specific definition is not otherwise provided, “alkyl group” refers to a substituted or unsubstituted linear or branched saturated aliphatic hydrocarbon group. The alkyl group does not contain a double or triple bond.

As an example, the alkyl group may be a C1 to C8 alkyl group, for example, a C1 to C7 alkyl group, a C1 to C6 alkyl group, a C1 to C5 alkyl group, or a C1 to C4 alkyl group. For example, the alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, when specific definition is not otherwise provided, “alkylene group” refers to a substituted or unsubstituted linear or branched divalent hydrocarbyl group having a specific number of carbon atoms that can link two different groups together. The alkylene group may refer to —(CH₂)ₙ— (where n is an integer of 1 to 8, for example, n is an integer of 1 to 4).

As an example, the alkylene group may be a C1 to C8 alkylene group, for example, a C1 to C7 alkylene group, a C1 to C6 alkylene group, a C1 to C5 alkylene group, or a C1 to C4 alkylene group. For example, the alkylene group may include a methylene group, an ethylene group, a propylene group, an isopropylene group, an n-butylene group, an isobutylene group, a sec-butylene group, a tert-butylene group, or a 2,2-dimethylpropylene group.

As used herein, when specific definition is not otherwise provided, “alkoxy group” refers to a monovalent —O-alkyl group in which the alkyl portion has a specific number of carbon atoms. The alkyl moiety of the alkoxy group may be a substituted or unsubstituted linear or branched alkyl group.

For example, the alkoxy group may be a C1 to C8 alkoxy group, for example, a C1 to C7 alkoxy group, a C1 to C6 alkoxy group, a C1 to C5 alkoxy group, or a C1 to C4 alkoxy group. For example, the C1 to C4 alkoxy may be methoxy (—OCH₃), ethoxy (—OCH₂CH₃), isopropoxy (—OCH(CH₃)₂), or tert-butyloxy (—OC(CH₃)₃).

As used herein, when specific definition is not otherwise provided, “cycloalkyl group” refers to a substituted or unsubstituted monovalent cyclic aliphatic saturated hydrocarbon group.

As an example, the cycloalkyl group may be a C3 to C20 cycloalkyl group, for example, a C3 to C10 cycloalkyl group, a C3 to C8 cycloalkyl group, a C3 to C7 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group.

As used herein, when specific definition is not otherwise provided, a “heterocycloalkyl group” refers to a cyclic aliphatic saturated group including at least one heteroatom containing N, O, S, P, Si, or any combination thereof in the cycloalkyl group. Two or more heterocycloalkyl groups may be directly linked through a sigma bond, or if the heterocycloalkyl group contains two or more rings, two or more rings may be fused to each other. When the heterocycloalkyl group is a fused ring, each ring may contain 1 to 3 heteroatoms.

For example, the heterocycloalkyl group may be a C3 to C20 heterocycloalkyl group, for example, a C3 to C10 heterocycloalkyl group, a C3 to C8 heterocycloalkyl group, a C3 to C7 heterocycloalkyl group, a C3 to C6 heterocycloalkyl group, a C3 to C5 heterocycloalkyl group, or a C3 to C4 heterocycloalkyl group. For example, the heterocycloalkyl group may be pyrrolidine, tetrahydrofuran, tetrahydrothiophene, or piperidine groups.

As used herein, when specific definition is not otherwise provided, “aryl group” refers to a substituted or unsubstituted aromatic ring group including all element of the ring having p-orbitals which form conjugation, and may be a monocyclic, polycyclic or fused-ring polycyclic (e.g., rings sharing adjacent pairs of carbon atoms) functional group.

For example, the aryl group may be a C3 to C20 aryl group, for example, a C3 to C10 aryl group, a C3 to C8 aryl group, a C3 to C7 aryl group, a C3 to C6 aryl group, a C3 to C5 aryl group, or a C3 to C4 aryl group. For example, the aryl group may be benzene, biphenyl, naphthalene, anthracene, phenanthrene, pyrene, or perylene groups.

As used herein, when specific definition is not otherwise provided, a “heteroaryl group” refers to an aromatic ring group including at least one heteroatom including N, O, S, P, Si, or any combination thereof in the aryl group. Two or more heteroaryl groups may be directly linked through a sigma bond, or if the heteroaryl group contains two or more rings, two or more rings may be fused to each other. When the heteroaryl group is a fused ring, each ring may contain 1 to 3 heteroatoms.

For example, the heteroaryl group may be a C3 to C20 heteroaryl group, for example, a C3 to C10 heteroaryl group, a C3 to C8 heteroaryl group, a C3 to C7 heteroaryl group, a C3 to C6 heteroaryl group, a C3 to C5 heteroaryl group, or a C3 to C4 heteroaryl group. For example, heteroaryl groups may be pyrazole, imidazole, thiazole, triazole, carbazole, pyridine, pyridazine, pyrimidine, pyrazine, triazine, indazole, indolizine, benzimidazole, benzothiazole, benzothiophene, benzopurine, isoquinoline, or purine groups.

As used herein, when specific definition is not otherwise provided, “alkenyl group” refers to a substituted or unsubstituted linear or branched aliphatic hydrocarbon group containing one or more double bonds. For example, the alkenyl group may be a C2 to C8 alkenyl group, for example, a vinyl group, an allyl group, a 1-propenyl group, a 1-methyl-1-propenyl group, a 2-propenyl group, a 2-methyl-2-propenyl group, a 1-butenyl group, a 2-butenyl group, or a 3-butenyl group.

As used herein, when specific definition is not otherwise provided, “cycloalkenyl group” refers to a cyclic aliphatic hydrocarbon group containing one or more double bonds. As an example, the cycloalkenyl group may be a C3 to C20 cycloalkenyl group.

As used herein, when specific definition is not otherwise provided, “alkynyl group” refers to a substituted or unsubstituted linear or branched aliphatic unsaturated hydrocarbon group containing one or more triple bonds. For example, the alkynyl group may be a C2 to C8 alkynyl group, for example, an ethynyl group, a 1-propynyl group, a 1-methyl-1-propynyl group, a 2-propynyl group, a 2-methyl-2-propynyl group, a 1-butynyl group, a 2-butynyl group, or a 3-butynyl group.

As used herein, when specific definition is not otherwise provided, “cycloalkynyl group” refers to a cyclic aliphatic unsaturated hydrocarbon group containing one or more triple bonds. As an example, the cycloalkynyl group may be a C3 to C20 cycloalkynyl group.

As used herein, when specific definition is not otherwise provided, “hydroxy group” refers to the —OH group.

As used herein, when specific definition is not otherwise provided, “halo” or “halogen group” means fluorine (F), chlorine (Cl), bromine (Br), or iodine (I).

As used herein, when specific definition is not otherwise provided, “*” indicates a linking point of a structural unit of a compound or a moiety of the compound.

A photoresist composition according to some embodiments includes an organometallic compound and a solvent.

The organometallic compound includes a ring and an aromatic ring substituted or fused to the ring.

The ring includes a metal and a first heteroatom and a second heteroatom bonded to the metal. The first heteroatom and the second heteroatom are each independently covalently bonded or coordinated to the metal, and at least one of the first heteroatom and the second heteroatom is coordinated to the metal. In some embodiments, the first heteroatom is coordinated to the metal.

The photoresist composition containing such an organometallic compound can form patterns with a size of about 20 nm or less using extreme ultraviolet rays, can achieve high resolution and low line edge roughness with just a single exposure process, and has moisture stability and environmental stability, which can reduce the critical dimension deviation between wafers and can reduce the occurrence of defects by reducing photoresist residues in non-exposed regions.

In the case of chemically amplified photoresists, intrinsic image blurring occurs as the H generated by the acid catalyst moves and the line edge roughness (LER) is deteriorated, and thus high resolution and low line edge roughness cannot be achieved with just a single exposure process using extreme ultraviolet rays.

On the other hand, in the case of the organometallic compound, when the organic ligand is dissociated by light absorption or secondary electrons generated thereby, negative tone patterning that is not removed by an organic developer may be enabled through crosslinking through oxo bonds with surrounding chains. The organometallic compound may have dramatically improved sensitivity while maintaining resolution and line edge roughness, making it possible to achieve high resolution and low line edge roughness with just a single exposure process using extreme ultraviolet rays.

However, conventional organometallic compounds are susceptible to environmental sensitivities such as moisture and heat due to their characteristics of being easily oxidized by moisture and heat. This causes a decrease in yield due to the large critical dimension deviation between wafers, and has poor storage stability, making it difficult to apply to mass production. In particular, when the organometallic compound contains a hydroxyl group (—OH) bonded to a metal, this moiety is highly reactive with moisture.

The organometallic compound according to some embodiments does not substitute a hydroxyl group (—OH) on a metal, but instead includes two heteroatoms bonded to the metal in a ring. In some embodiments, even when moisture attacks, the two heteroatoms remain because the bonds are difficult to break at the same time, and, due to the stability and non-hydrophilic nature of the aromatic ring substituted or fused to the ring, moisture stability and environmental stability can be improved, thereby reducing a critical dimension deviation between wafers and enabling mass production.

An organometallic compound according to some embodiments is represented by Chemical Formula 1.

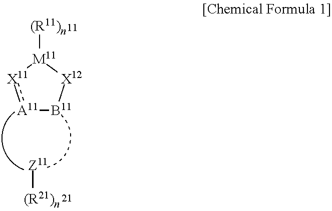

In Chemical Formula 1, M¹¹ represents a metal, and X¹¹ and X¹² represent first and second heteroatoms bonded to the metal. M¹¹, X¹¹, X¹², A¹¹, and B¹¹ form a ring. In some embodiments, Z¹¹ may be an aromatic ring that is bonded to A¹¹ (e.g., substituted to A¹¹), or Z¹¹ may be a linking group with Z¹¹, A¹¹, and B¹¹ forming an aromatic ring that can be fused to the ring. In some embodiments, A¹¹ does not form an aromatic ring with Z¹¹, but is bonded thereto.

For example, in Chemical Formula 1, M¹¹, which is a metal, and X¹¹, which is a first heteroatom, may be coordinated, and M¹¹, which is a metal, and X¹², which is a second heteroatom, may be covalently bonded. In Chemical Formula 1, the dashed line between X¹¹ and A¹¹ indicates that when M¹¹ and X¹¹ are coordinated, the bond between X¹¹ and A¹¹ may be a double bond.

While not intended to be bound by a specific theory, but as described later, when M¹¹ is tin (Sn) and A¹¹=X¹¹ is carbonyl (C═O), considering the oxidation number of tin (Sn), the O of carbonyl (C═O) group does not have a separate charge and is coordinated to tin (Sn), it may be represented by A¹¹=X¹¹-M¹¹(C═O—Sn). However, when considering energy stabilization, it is quite possible that the electrons are actually delocalized rather than localized. However, when represented by A¹¹-X¹¹-M¹¹(C—O—Sn), the oxygen (O) may also mean that it has a separate charge, which may lead to confusion about the oxidation number of tin (Sn), and thus, here, it is represented by A¹¹=X¹¹-M¹¹(C═O—Sn).

M¹¹ is a metal including Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe, and may be, for example Sn.

X¹¹ and X¹² are each independently O, S, or NR′, wherein R′ is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. Herein, the combination thereof may include, for example, a hydroxyl-alkyl group in which an alkyl group and a hydroxy group are combined, an alkyl-aryl group in which an alkyl group and an aryl group are combined, a halogenated alkyl group in which an alkyl group is substituted with a halogen, or a hydroxyl-aryl group in which an aryl group is substituted with a hydroxy group, etc.

A¹¹ and B¹¹ are each independently a linking group including a single bond, a double bond, an alkylene group, O, S, NR′, NHC(═O), SO, SO₂, CO, O—CO—O, C(═O)O, OCO, or any combination thereof. Herein, the combination thereof may be, for example, alkylene-CO in which an alkylene group and CO are combined, alkylene-NR′ in which an alkylene group and NR′ are combined, or NR′CO in which NR′ and CO are combined.

As described above, Z¹¹ is an aromatic ring and may be substituted at the A¹¹ site of the ring, or Z¹¹ may be a linking group, with Z¹¹, A¹¹, and B¹¹ forming an aromatic ring that is fused to the ring.

In Chemical Formula 1, the solid line between Z¹¹ and A¹¹ indicates the case where Z¹¹ is substituted for A¹¹, and the dashed line between Z¹¹ and B¹¹ indicates that Z¹¹, A¹¹, and B¹¹ form an aromatic ring and are fused to the ring.

When Z¹¹ is an aromatic ring, the aromatic ring may be an aryl group, a heteroaryl group, or any combination thereof. Herein, the combination thereof may be, for example, biphenyl in which benzene and benzene are linked by a single bond, naphthalene in which benzene and benzene are fused, or phenyl furan in which furan is substituted with benzene.

When Z¹¹ is fused to A¹¹ and B¹¹ to form an aromatic ring, Z¹¹ is a linking group including a single bond, double bond, alkylene group, O, S, NR′, NHC(═O), SO, SO₂, CO, O—CO—O, C(═O)O, OCO, or any combination thereof. Herein, the combination thereof may be, for example, alkylene-CO in which an alkylene group and CO are combined, alkylene-NR′ in which an alkylene group and NR′ are combined, or NR′CO in which NR′ and CO are combined.

R′ is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. Herein, the combination thereof may include, for example, a hydroxyl-alkyl group in which an alkyl group and a hydroxy group are combined, an alkyl-aryl group in which an alkyl group and an aryl group are combined, a halogenated alkyl group in which an alkyl group is substituted with a halogen, or a hydroxyl-aryl group in which an aryl group is substituted with a hydroxy group, etc.

R¹¹ and R²¹ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. Herein, the combination thereof may include, for example, a hydroxyl-alkyl group in which an alkyl group and a hydroxy group are combined, an alkyl-aryl group in which an alkyl group and an aryl group are combined, a halogenated alkyl group in which an alkyl group is substituted with a halogen, or a hydroxyl-aryl group in which an aryl group is substituted with a hydroxy group, etc.

Meanwhile, solvent or remaining reactants may optionally be coordinated to M¹¹. In this case, R¹¹ may include a solvent (sol.). The solvent may be an organic solvent capable of coordination, for example, pyridine, tetrahydrofuran (THF), ether, alcohol, amine, acetone, dimethyl sulfoxide (DMSO), dimethylformamide (DMF), acetic acid, or any combination thereof

n¹¹ is the number of substitutable positions of M¹¹, and may be, for example, an integer of 0 or more, an integer of 1 or more, an integer of 2 or more, an integer of 3 or more, an integer of 4 or more, or an integer of 5 or more, for example, an integer of 6 or less, or an integer of 5 or less, an integer of 4 or less, an integer of 3 or less, an integer of 2 or less, or an integer of 1 or less. As an example, when M¹¹ is tin (Sn), an oxidation number of tin (Sn) may be trivalent or tetravalent, and the number (n¹¹) of the substituent (R¹¹) that can be substituted for tin (Sn) may be up to 3 by subtracting only the bond with the second heteroatom (X¹²) covalently bonded to the tin (Sn) without subtracting the bond with the first heteroatom (X¹¹) coordinated to tin (Sn). Therefore, in Chemical Formula 1, n¹¹ may be an integer obtained by subtracting 1 from the oxidation number of M¹¹.

n²¹ is the number of substitutable positions of the aromatic ring, and may be for example, an integer of 0 or more, an integer of 1 or more, an integer of 2 or more, an integer of 3 or more, an integer of 4 or more, an integer of 5 or more, an integer of 6 or more, an integer of 10 or more, an integer of 20 or more, or an integer of 30 or more, for example, an integer of 30 or less, an integer of 20 or less, an integer of 10 or less, an integer of 6 or less, an integer of 5 or less, an integer of 4 or less, an integer of 3 or less, an integer of 2 or less, or an integer of 1 or less. For example, when Z¹¹ is an aromatic ring substituted for A¹¹ and the aromatic ring is benzene, by subtracting the bond with A¹¹, the total number (n²¹) of substituents (R²¹) that can be substituted for benzene may be up to 5, including hydrogen groups.

Meanwhile, the organometallic compound represented by Chemical Formula 1 may be linked to another organometallic compound represented by Chemical Formula 1, and in this case, the organometallic compound may be a supramolecular structure with a ring-type structure or a ladder-type structure. At this time, the organometallic compound may be linked to other organometallic compounds by any one of R¹¹s substituted for M¹¹, any one of R²¹s substituted for Z¹¹, or R′ when A¹¹ and/or B¹¹ are NR′. In this case, R¹¹, R²¹, or R′ are each independently a linking group including a single bond, double bond, alkylene group, O, S, NR′, NHC(═O), SO, SO₂, CO, O—CO—O, C(═O)O, OCO, or any combination thereof.

As an example, the organometallic compound may be represented by Chemical Formula 2. That is, the organometallic compound represented by Chemical Formula 2 is a case in which Z¹¹ is substituted for a ring as an aromatic ring.

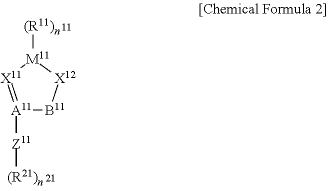

In Chemical Formula 2, M¹¹, X¹¹, X¹², A, B¹¹, R¹¹, R²¹, n¹¹, and n²¹ are the same as described in Chemical Formula 1, and thus repetitive explanation will be omitted. However, Z¹¹ is an aromatic ring in Chemical Formula 2, and the aromatic ring may be an aryl group, a heteroaryl group, or a combination thereof.

As an example, the organometallic compound represented by Chemical Formula 2 may be represented by Chemical Formula 2-1 or 2-2.

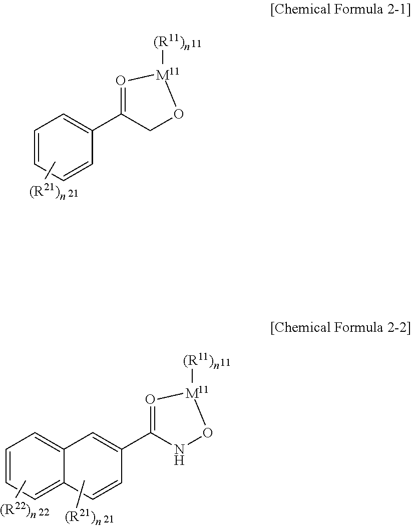

In Chemical Formulas 2-1 and 2-2, M¹¹, R¹¹, R²¹, and n¹¹ are the same as described in Chemical Formula 1, and thus repetitive explanation will be omitted. However, in some embodiments of Chemical Formula 2-1, n²¹ is an integer of 5, and in Chemical Formula 2-2, n²¹ is an integer of 3.

In addition, in Chemical Formula 2-2, R²² may be a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or a linking group including a single bond, a double bond, an alkylene group, 0, S, NR′, NHC(═O), SO, SO₂, CO, O—CO—O, C(═O)O, OCO, or any combination thereof. In some embodiments, n²² is an integer of 4.

In Chemical Formula 2-1, when M¹¹ is tin (Sn), R¹¹ is all CH₃, n¹¹ is an integer of 3, and R²¹ is all hydrogen, it may be represented by Chemical Formula 2-1-1.

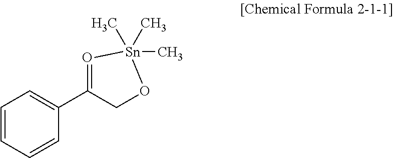

In Chemical Formula 2-2, when M¹¹ is tin (Sn), R¹¹ is both CH₃, n¹¹ is an integer of 3, R²¹ and R²² are both hydrogen groups, and n²² is an integer of 4, it may be represented by Chemical Formula 2-2-1.

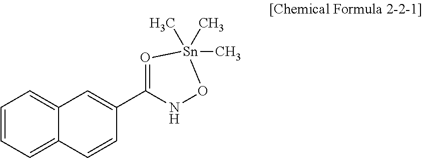

The organometallic compound may be represented by Chemical Formula 3. That is, the organometallic compound represented by Chemical Formula 3 is a case where Z¹¹ is a linking group with Z¹¹, A¹¹, and B¹¹ forming an aromatic ring that is fused to the ring.

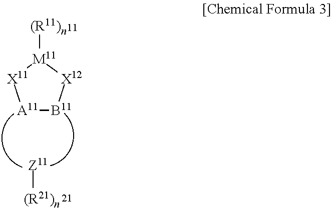

In Chemical Formula 3, M¹¹, X¹¹, X¹², A¹¹, B¹¹, R¹¹, R²¹, n¹¹ and n²¹ are the same as described in Chemical Formula 1, and thus repetitive explanation will be omitted. However, in Chemical Formula 3, Z¹¹ is a linking group, such as a single bond, double bond, alkylene group, O, S, NR′, NHC(═O), SO, SO₂, CO, O—CO—O, C(═O)O, OCO, or any combination thereof.

As an example, the organometallic compound represented by Chemical Formula 3 may be represented by Chemical Formula 3-1.

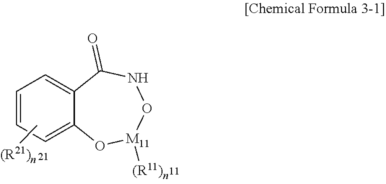

In Chemical Formula 3-1, M¹¹, R¹¹, R²¹, and n¹¹ are the same as described in Chemical Formula 1, and thus repetitive explanation will be omitted. In some embodiments, in Chemical Formula 3-1, n²¹ is an integer of 4.

In Chemical Formula 3-1, when M¹¹ is tin (Sn), R¹¹ is all CH₃, n¹¹ is an integer of 2, R²¹ is all hydrogen, and n²¹ is an integer of 4, it may be represented by Chemical Formula 3-1-1.

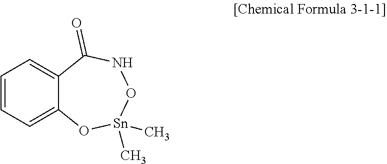

The organometallic compound may be represented by Chemical Formula 4. That is, the organometallic compound represented by Chemical Formula 4 is a supramolecule with a cyclic structure, and is a compound where three organometallic compounds represented by Chemical Formula 2 are linked to each other (e.g., bonded) through the linking group of R²¹. For example, R²¹ of the first organometallic compound may be linked to M¹¹ of the second organometallic compound, R²¹ of the second organometallic compound may be linked to M¹¹ of the third organometallic compound, and R²¹ of the third organometallic compound may be linked to M¹¹ of the first organometallic compound. In Chemical Formula 4, R²¹s linked to other organometallic compounds are represented by X²¹, X²², and X²³, respectively.

As shown in Chemical Formula 4, in some embodiments, when the organometallic compound has a cyclic structure, sensitivity can be improved and high resolution can be achieved with only a single exposure process using extreme ultraviolet rays. In some embodiments, moisture stability and environmental stability can be improved, and as the molecular size is small by including only 2 to 4 metals, line edge roughness can be further improved.

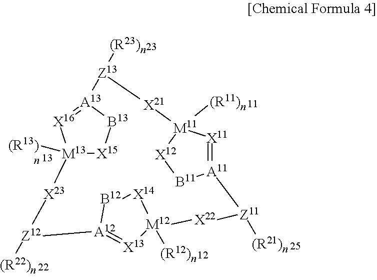

In Chemical Formula 4, M¹¹ to M¹³ are each independently a metal including Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe. More detailed descriptions therefor are the same as that described for M¹¹ in Chemical Formula 1, and thus repeated descriptions are omitted.

X¹¹ to X¹⁶ are each independently 0, 5, or NR′. More detailed descriptions therefor are the same as that described for X¹¹ and X¹² in Chemical Formula 1, and thus repeated descriptions are omitted.

A¹¹ to A¹³, B¹¹ to B¹³, and X²¹ to X²³ are each independently a linking group including a single bond, a double bond, an alkylene group, O, S, NR′, NHC(═O), SO, SO₂, CO, O—CO—O, C(═O)O, OCO, or any combination thereof. More detailed descriptions therefor are the same as that described for A¹¹ and B¹¹ in Chemical Formula 1, and thus repeated descriptions are omitted.

In Chemical Formula 4, Z¹¹ to Z¹³ are each independently aromatic rings substituted for A¹¹ to A¹³. More detailed descriptions therefor are the same as that described for Z¹¹ in Chemical Formula 1, and thus repeated descriptions are omitted.

R¹¹ to R¹³ and R²¹ to R²³ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹¹ to R¹³ are solvents coordinated to M¹¹ to M¹³, respectively. More detailed descriptions therefor are the same as that described for R¹¹ and R²¹ in Chemical Formula 1, and thus repeated descriptions are omitted.

R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. More detailed descriptions therefor are the same as that described for R′ in Chemical Formula 1, and thus repeated descriptions are omitted.

n¹¹ to n¹³ are each independently the numbers of substitutable positions of M¹¹ to M¹³, and may be, for example, an integer of 0 or more, an integer of 1 or more, an integer of 2 or more, an integer of 3 or more, an integer of 4 or more, or an integer of 5 or more, for example, an integer of 6 or less, or an integer of 5 or less, an integer of 4 or less, an integer of 3 or less, an integer of 2 or less, or an integer of 1 or less. For example, when M¹¹ is tin (Sn), the oxidation number of tin (Sn) may be trivalent or tetravalent, and the number (n¹¹) of substituents (R¹¹) that can be substituted for tin (Sn) may be up to 2 by subtracting the bond with the second heteroatom (X¹²) covalently bonded, and the bond with the aromatic ring (Z¹³) of another organometallic compound through the linking group (X²¹) without subtracting the bond with the first heteroatom (X¹¹) coordinated to tin (Sn). Therefore, in Chemical Formula 4, n¹¹ to n¹³ may be an integer obtained by subtracting 2 from the oxidation numbers of M¹¹ to M¹³.

n²¹ to n²³ are each independently the replaceable digits of Z¹¹ to Z¹³. More detailed descriptions therefor are the same as that described for n²¹ in Chemical Formula 1, and thus repeated descriptions are omitted.

n²¹ to n²³ are the number of substitutable positions of Z¹¹ to Z¹³, and may be for example, an integer of 0 or more, an integer of 1 or more, an integer of 2 or more, an integer of 3 or more, an integer of 4 or more, an integer of 5 or more, an integer of 6 or more, an integer of 10 or more, an integer of 20 or more, or an integer of 30 or more, for example, an integer of 30 or less, an integer of 20 or less, an integer of 10 or less, an integer of 6 or less, an integer of 5 or less, an integer of 4 or less, an integer of 3 or less, an integer of 2 or less, or an integer of 1 or less. For example, when Z¹¹ is benzene, by subtracting the bond with A¹¹ and the bond with X²², the total number (n²¹) of substituents (R²¹) that can be substituted for benzene may be up to 4, including hydrogen groups.

As an example, the organometallic compound represented by Chemical Formula 4 may be represented by Chemical Formula 4-1.

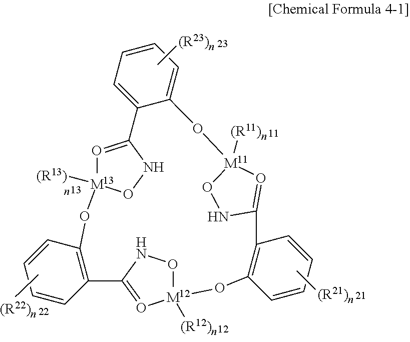

In Chemical Formula 4-1, M¹¹ to M¹³, R¹¹ to R¹³, R²¹ to R²³, and n¹¹ to n¹³ are the same as described in Chemical Formula 4, and thus repetitive explanation will be omitted. However, in Chemical Formula 4-1, n²¹ to n²³ are integers of 4.

In Chemical Formula 4-1, when M¹¹ to M¹³ are tin (Sn), R¹¹ to R¹³ are all CH₃, n¹¹ to n¹³ are integers of 2, and one R²¹ to R²³ in each aromatic ring is fluorine (F), the remaining R²¹ to R²³ are all hydrogen groups, and n²¹ to n²³ are integers of 4, it may be represented by Chemical Formula 4-1-1.

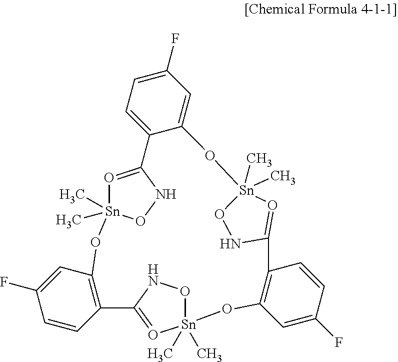

The organometallic compound may be represented by Chemical Formula 5. That is, the organometallic compound represented by Chemical Formula 5 is a case where the substituents (R¹¹s) of M¹¹ are fused to form a ring.

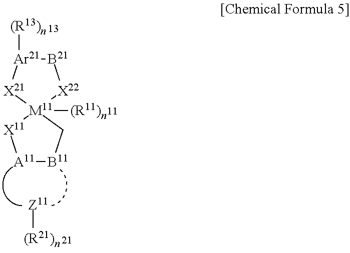

In Chemical Formula 5, M, X¹¹, X¹², A¹¹, B¹¹, Z¹¹, R¹¹, R²¹, and n²¹ are the same as described in Chemical Formula 1, and thus repetitive explanation will be omitted.

In Chemical Formula 5, X²¹ and X²² are each independently, S, or NR′. More detailed descriptions therefor are the same as that described for X¹¹ and X¹² in Chemical Formula 1, and thus repeated descriptions are omitted.

B²¹ is a linking group including a single bond, a double bond, an alkylene group, O, S, NR′, NHC(═O), SO, SO₂, CO, O—CO—O, C(═O)O, OCO, or any combination thereof. More detailed descriptions therefor are the same as that described for B¹¹ in Chemical Formula 1, and thus repeated descriptions are omitted.

Ar²¹ is an aromatic ring substituted for X²¹ and B²¹, and the aromatic ring may be an aryl group, a heteroaryl group, or a combination thereof. Herein, the combination thereof may be, for example, biphenyl in which benzene and benzene are linked by a single bond, naphthalene in which benzene and benzene are fused, or phenyl furan in which furan is substituted with benzene.

R¹³ is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹³ is a linking group including a single bond, a double bond, an alkylene group, O, S, NR′, NHC(═O), SO, SO₂, CO, O—CO—O, C(═O)O, OCO, or any combination thereof. More detailed descriptions therefor are the same as that described for R¹¹ and R²¹ in Chemical Formula 1, and thus repeated descriptions are omitted.

R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. More detailed descriptions therefor are the same as that described for R′ in Chemical Formula 1, and thus repeated descriptions are omitted.

n¹¹ is the number of substitutable positions of M¹¹, and may be, for example, an integer of 0 or more, an integer of 1 or more, an integer of 2 or more, an integer of 3 or more, an integer of 4 or more, or an integer of 5 or more, for example, an integer of 6 or less, or an integer of 5 or less, an integer of 4 or less, an integer of 3 or less, an integer of 2 or less, or an integer of 1 or less. As an example, when M¹¹ is tin (Sn), an oxidation number of tin (Sn) may be trivalent or tetravalent, and the number (n¹¹) of the substituent (R¹¹) that can be substituted for tin (Sn) may be up to 1 by subtracting the bond with the covalently bonded second heteroatom (X¹²), the bond with X²¹, and the bond with X²² without subtracting the bond with the first heteroatom (X¹¹) coordinated to tin (Sn). Therefore, in Chemical Formula 5, n¹¹ may be an integer obtained by subtracting 3 from the oxidation number of M¹¹.

Meanwhile, solvent or remaining reactants may optionally be coordinated to M¹¹. In this case, R¹¹ may include a solvent (sol.). The solvent may be an organic solvent capable of coordination, for example, pyridine, tetrahydrofuran (THF), ether, alcohol, amine, acetone, dimethyl sulfoxide (DMSO), dimethylformamide (DMF), acetic acid, or any combination thereof

n¹³ is the number of substitutable positions of Ar²¹, and may be for example, an integer of 0 or more, an integer of 1 or more, an integer of 2 or more, an integer of 3 or more, an integer of 4 or more, an integer of 5 or more, an integer of 6 or more, an integer of 10 or more, an integer of 20 or more, or an integer of 30 or more, for example, an integer of 30 or less, an integer of 20 or less, an integer of 10 or less, an integer of 6 or less, an integer of 5 or less, an integer of 4 or less, an integer of 3 or less, an integer of 2 or less, or an integer of 1 or less. For example, when Ar²¹ is benzene, by subtracting the bonds with X²¹ and B²¹, the total number (n¹³) of substituents (R¹³) that can be substituted for benzene may be up to 4, including hydrogen groups.

The organometallic compound may be represented by Chemical Formula 6. That is, the organometallic compound represented by Chemical Formula 6 is a supramolecule with a cyclic structure, and is a compound where four organometallic compounds represented by Chemical Formula 2 are linked to each other through the linking group of R²¹ and B¹¹. For example, R²¹ and B¹¹ of the first organometallic compound are linked to M¹¹ of the second organometallic compound to form a ring, R²¹ and B¹¹ of the second organometallic compound are linked to M¹¹ of the third organometallic compound to form a ring, R²¹ and B¹¹ of the third organometallic compound are linked to M¹¹ of the fourth organometallic compound to form a ring, and R²¹ and B¹¹ of the fourth organometallic compound are linked to M¹¹ of the first organometallic compound to form a ring. In Chemical Formula 6, R²¹s linked to other organometallic compounds are represented by X²¹, X²², X²³, and X²⁴, respectively.

As shown in Chemical Formula 6, when the organometallic compound has a cyclic structure, sensitivity is improved and high resolution can be achieved with only a single exposure process using extreme ultraviolet rays, moisture stability and environmental stability are improved, and as the molecular size is small by containing only 2 to 4 metals, line edge roughness can be further improved.

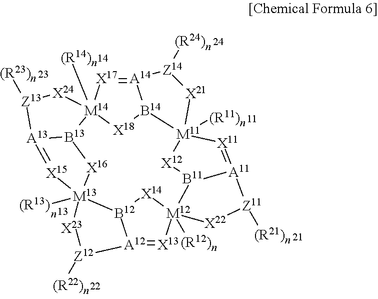

In Chemical Formula 6, M¹¹ to M¹⁴ are each independently a metal including Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe. More detailed descriptions therefor are the same as that described for M¹¹ in Chemical Formula 1, and thus repeated descriptions are omitted.

X¹¹ to X¹⁸ are each independently 0, 5, or NR′. More detailed descriptions therefor are the same as that described for X¹¹ and X¹² in Chemical Formula 1, and thus repeated descriptions are omitted.

A¹¹ to A¹⁴, and X²¹ to X²⁴ are each independently a linking group including a single bond, a double bond, an alkylene group, O, S, NR′, NHC(═O), 50, SO₂, CO, O—CO—O, C(═O)O, OCO, or any combination thereof. More detailed descriptions therefor are the same as that described for A¹¹ in Chemical Formula 1, and thus repeated descriptions are omitted.

Meanwhile, B¹¹ to B¹⁴ may be a linking group having a substituent bonded to the metal of another organometallic compound, for example, N, or a combination of N with a single bond, a double bond, an alkylene group, O, S, NR′, NHC(═O), 50, SO₂, CO, O—CO—O, C(═O)O, or OCO.

Z¹¹ to Z¹⁴ are each independently aromatic rings substituted for A¹ to A¹⁴ and X¹¹ to X¹⁴. More detailed descriptions therefor are the same as that described for Z¹¹ in Chemical Formula 1, and thus repeated descriptions are omitted.

R¹¹ to R¹⁴ and R²¹ to R²⁴ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. More detailed descriptions therefor are the same as that described for R¹¹ and R²¹ in Chemical Formula 1, and thus repeated descriptions are omitted.

R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. More detailed descriptions therefor are the same as that described for R′ in Chemical Formula 1, and thus repeated descriptions are omitted.

n¹¹ to n¹⁴ are each independently the numbers of substitutable positions of M¹¹ to M¹⁴, and may be, for example, an integer of 0 or more, an integer of 1 or more, an integer of 2 or more, an integer of 3 or more, an integer of 4 or more, or an integer of 5 or more, for example, an integer of 6 or less, or an integer of 5 or less, an integer of 4 or less, an integer of 3 or less, an integer of 2 or less, or an integer of 1 or less. As an example, when M¹¹ is tin (Sn), an oxidation number of tin (Sn) may be trivalent or tetravalent, and the number (n¹¹) of the substituent (R¹¹) that can be substituted for tin (Sn) may be up to 1 by subtracting the bond with the covalently bonded second heteroatom (X¹²), the bond with the aromatic ring (Z¹⁴) of another organometallic compound through the linking group (X²¹), and the bond with B¹⁴ of another organometallic compound, without subtracting the bond with the first heteroatom (X¹¹) coordinated to tin (Sn). Therefore, in Chemical Formula 6, n¹¹ to n¹⁴ are each independently integers obtained by subtracting 3 from the oxidation numbers of M¹¹ to M¹⁴.

Meanwhile, solvent or remaining reactants may optionally be coordinated to M¹¹ to M¹⁴. In this case, R¹¹ to R¹⁴ may include a solvent (sol.). The solvent may be an organic solvent capable of coordination, for example, pyridine, tetrahydrofuran (THF), ether, alcohol, amine, acetone, dimethyl sulfoxide (DMSO), dimethylformamide (DMF), acetic acid, or a combination thereof

n²¹ to n²⁴ are each independently the numbers of substitutable positions of Z¹¹ to Z¹⁴. More detailed descriptions therefor are the same as that described for n²¹ in Chemical Formula 1, and thus repeated descriptions are omitted.

n²¹ to n²⁴ are the numbers of substitutable positions of Z¹¹ to Z¹⁴, and may be for example, an integer of 0 or more, an integer of 1 or more, an integer of 2 or more, an integer of 3 or more, an integer of 4 or more, an integer of 5 or more, an integer of 6 or more, an integer of 10 or more, an integer of 20 or more, or an integer of 30 or more, for example, an integer of 30 or less, an integer of 20 or less, an integer of 10 or less, an integer of 6 or less, an integer of 5 or less, an integer of 4 or less, an integer of 3 or less, an integer of 2 or less, or an integer of 1 or less. For example, when Z¹¹ is benzene, by subtracting the bond with A¹¹ and the bond with X²², the total number (n²¹) of substituents (R²¹) that can be substituted for benzene may be up to 4, including hydrogen groups.

As an example, the organometallic compound represented by Chemical Formula 6 may be represented by Chemical Formula 6-1.

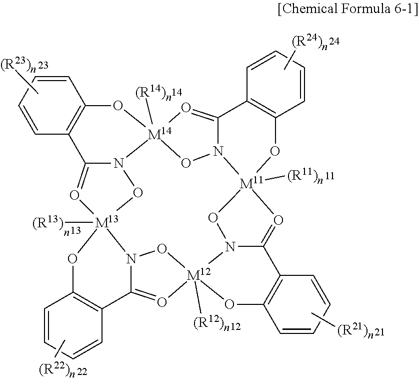

In Chemical Formula 6-1, M¹¹ to M¹⁴, R¹¹ to R¹⁴, R²¹ to R²⁴, and n¹¹ to n¹⁴ are the same as described in Chemical Formula 6, and thus repetitive explanation will be omitted. However, in Chemical Formula 6-1, n²¹ to n²⁴ are integers of 4.

In Chemical Formula 6-1, when M¹¹ to M¹⁴ are tin (Sn), n¹¹ to n¹⁴ are 2, one of each of R¹¹ to R¹⁴ is CH₃, the other of each of R¹¹ to R¹⁴ is sol, R²¹ to R²⁴ are all hydrogen groups, and n²¹ to n²⁴ are integers of 4, it may be represented by Chemical Formula 6-1-1. In Chemical Formula 6-1-1, each Sol substituted for tin (Sn) represents a solvent coordinated to tin (Sn).

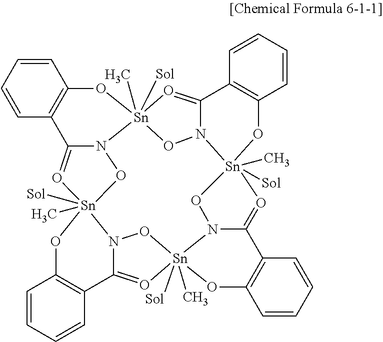

The organometallic compound may be represented by Chemical Formula 7. That is, the organometallic compound represented by Chemical Formula 7 is a supramolecule with a ladder-type structure, and two metals (M¹¹) of the organometallic compound represented by Chemical Formula 1 and a coordinated first heteroatom (X¹¹) are linked to each other to form a ring. For example, X¹¹ of the first organometallic compound is linked to M¹¹ of the second organometallic compound, and X¹¹ of the second organometallic compound is connected to M¹¹ of the first organometallic compound to form a ring.

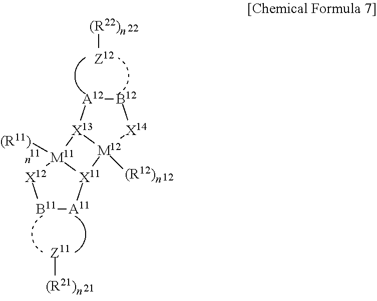

In Chemical Formula 7, M¹¹ and M¹² are each independently a metal including Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe. More detailed descriptions therefor are the same as that described for M¹¹ in Chemical Formula 1, and thus repeated descriptions are omitted.

X¹¹ to X¹⁴ are each independently O, S, or NR′. More detailed descriptions therefor are the same as that described for X¹¹ and X¹² in Chemical Formula 1, and thus repeated descriptions are omitted. At this time, because X¹¹ of the first organometallic compound is coordinated to M¹¹, X¹¹ can be bonded with A¹¹ and M¹² of the second organometallic compound, and X¹² can be bonded with A¹² and M¹¹ of the first organometallic compound.

A¹¹, A¹², B¹¹, and B¹² are each independently a linking group including a single bond, a double bond, an alkylene group, O, S, NR′, NHC(═O), SO, SO₂, CO, O—CO—O, C(═O)O, OCO, or any combination thereof. More detailed descriptions therefor are the same as that described for A¹¹ and B¹¹ in Chemical Formula 1, and thus repeated descriptions are omitted.

Z¹¹ and Z¹² are each independently aromatic rings substituted for A¹¹, or Z¹¹ and Z¹² are each independently linking groups including a single bond, a double bond, an alkylene group, O, S, NR′, NHC(═O), SO, SO₂, CO, O—CO—O, C(═O)O, OCO, or any combination thereof that is fused to A¹¹ and B¹¹ or A¹² and B¹² to form an aromatic ring. More detailed descriptions therefor are the same as that described for Z¹¹ in Chemical Formula 1, and thus repeated descriptions are omitted.

R¹¹ and R¹² are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹¹ and R¹² are solvents coordinated to M¹¹ and M¹², respectively. More detailed descriptions therefor are the same as that described for R¹¹ in Chemical Formula 1, and thus repeated descriptions are omitted.

R²¹ and R²² are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R²¹ and R²² are each independently a linking group including a single bond, a double bond, an alkylene group, O, S, NR′, NHC(═O), SO, SO₂, CO, O—CO—O, C(═O)O, OCO, or any combination thereof. More detailed descriptions therefor are the same as that described for R²¹ in Chemical Formula 1, and thus repeated descriptions are omitted.

R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. More detailed descriptions therefor are the same as that described for R′ in Chemical Formula 1, and thus repeated descriptions are omitted.

n¹¹ and n¹² are each independently the numbers of substitutable positions of M¹¹ and M¹², and may be, for example, an integer of 0 or more, an integer of 1 or more, an integer of 2 or more, an integer of 3 or more, an integer of 4 or more, or an integer of 5 or more, for example, an integer of 6 or less, or an integer of 5 or less, an integer of 4 or less, an integer of 3 or less, an integer of 2 or less, or an integer of 1 or less. As an example, when M¹¹ is tin (Sn), an oxidation number of tin (Sn) may be trivalent or tetravalent, and the number (n¹¹) of the substituent (R¹¹) that can be substituted for tin (Sn) may be up to 2 by subtracting the bond with the covalently bonded second heteroatom (X¹²) and the bond with the first heteroatom (X¹³) of another organometallic compound without subtracting the bond with the first heteroatom (X¹¹) coordinated to tin (Sn)

Therefore, in Chemical Formula 7, n¹¹ and n¹² may be an integer obtained by subtracting 2 from the oxidation numbers of M¹¹ to M¹².

n²¹ and n²² are each independently the number of substitutable positions of Z¹¹ and Z¹². More detailed descriptions therefor are the same as that described for n²¹ in Chemical Formula 1, and thus repeated descriptions are omitted

As an example, the organometallic compound represented by Chemical Formula 7 may be represented by Chemical Formulas 7-1 to 7-3.

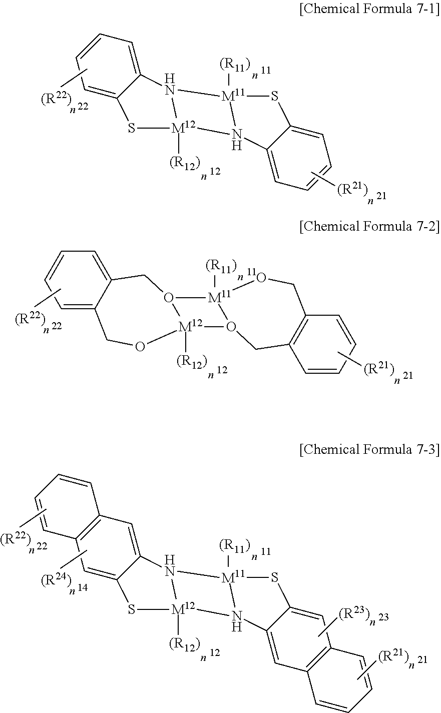

In Chemical Formulas 7-1 to 7-3, M¹¹, M¹², R^{D}, R¹², R²¹, R²², n¹¹, and n¹² are the same as described in Chemical Formula 7, and thus repetitive explanation will be omitted. However, in Chemical Formula 7-1, n²¹ and n²² are integers of 4.

R²³ and R²⁴ may be a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or a linking group including a single bond, a double bond, an alkylene group, O, S, NR′, NHC(═O), SO, SO₂, CO, O—CO—O, C(═O)O, OCO, or any combination thereof. n²³ and n²⁴ are integers of 2.

In Chemical Formulas 7-1 to 7-3, when M¹¹ and M¹² are tin (Sn), n¹¹ and n¹² are integers of 3, two of each of R¹¹ and R¹² are CH₃, the other of each of R¹¹ and R¹² is sol, both R²¹ and R²² are hydrogen, n²¹ and n²² are 4, both R²³ and R²⁴ are hydrogen, and n²³ and n²⁴ are integers of 2, it may be represented by Chemical Formulas 7-1-1 to 7-3-1. In Chemical Formulas 7-1-1 to 7-3-1, each Sol substituted for tin (Sn) represents a solvent coordinated to tin (Sn).

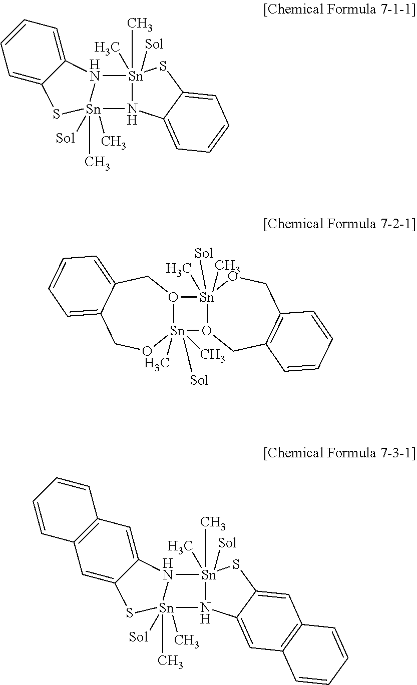

The organometallic compound may be represented by Chemical Formula 8. That is, the organometallic compound represented by Chemical Formula 8 has a structure in which the organometallic compound of the ladder-type structure represented by Chemical Formula 7 is repeated. For example, Z¹¹ of the first organometallic compound forms an aromatic ring with A¹² and B¹² of the second organometallic compound.

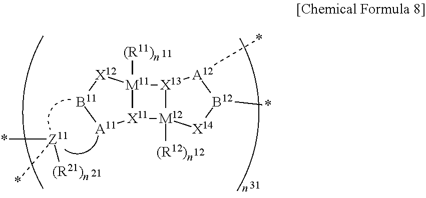

In Chemical Formula 8, M¹¹, M¹², X¹¹ to X¹⁴, A¹¹, A¹², B¹¹, B¹², R¹¹, R¹², R²¹, Z¹¹, n¹¹, n¹², and n²¹ are the same as described in Chemical Formula 7, and thus repetitive explanation will be omitted.

In Chemical Formula 8, n³¹ is the repeating number of the organometallic compound, and may be for example, an integer of 1 or more, an integer of 2 or more, an integer of 3 or more, an integer of 4 or more, an integer of 5 or more, an integer of 10 or more, an integer of 20 or more, an integer of 60 or more, an integer of 40 or more, an integer of 50 or more, an integer of 40 or more, an integer of 70 or more, an integer of 80 or more, an integer of 90 or more, or an integer of 100 or more, and for example, an integer of 100 or less, an integer of 90 or less, an integer of 80 or less, an integer of 70 or less, an integer of 60 or less, an integer of 50 or less, an integer of 40 or less, an integer of 30 or less, an integer of 20 or less, an integer of 10 or less, an integer of 6 or less, an integer of 5 or less, an integer of 4 or less, an integer of 3 or less, an integer of 2 or less, or an integer of 1 or less.

As an example, the organometallic compound represented by Chemical Formula 8 may be represented by Chemical Formula 8-1.

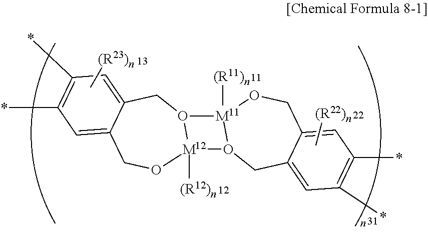

In Chemical Formula 8-1, M¹¹, M¹², R¹¹, R¹², n¹¹, and n¹² are the same as described in Chemical Formula 7, and thus repetitive explanation will be omitted. However, in Chemical Formula 8-1, n¹³ and n²² are integers of 2.

R²² and R²³ are a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. More detailed descriptions therefor are the same as that described for R²¹ in Chemical Formula 1, and thus repeated descriptions are omitted.

In Chemical Formula 8-1, when M¹¹ and M¹² are tin (Sn), n¹¹ and n¹² are integers of 3, two of each of R¹¹ and R¹² are CH₃, the other of each of R¹¹ and R¹² is sol, both R²¹ and R²² are hydrogen, and n¹³ and n²² are 2, it may be represented by Chemical Formula 8-1-1. In Chemical Formula 8-1-1, each Sol substituted for tin (Sn) represents a solvent coordinated to tin (Sn).

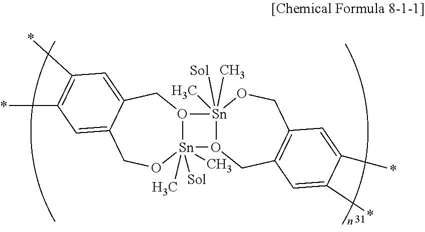

The organometallic compound according to some embodiments may be formed by coordinating a metal precursor including a metal and an organic ligand including an aromatic ring in which first and second heteroatoms bonded with the metal are substituted.

The metal precursor may be represented by Chemical Formula 9.

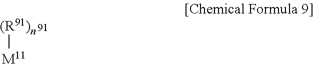

In Chemical Formula 9, M¹¹ is a metal including Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe. More detailed descriptions therefor are the same as that described for M¹¹ in Chemical Formula 1, and thus repeated descriptions are omitted.

R⁹¹ is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. More detailed descriptions therefor are the same as that described for R¹¹ in Chemical Formula 1, and thus repeated descriptions are omitted.

n⁹¹ is the number of substitutable positions of M¹¹, and may be, for example, an integer of 0 or more, an integer of 1 or more, an integer of 2 or more, an integer of 3 or more, an integer of 4 or more, or an integer of 5 or more, for example, an integer of 6 or less, or an integer of 5 or less, an integer of 4 or less, an integer of 3 or less, an integer of 2 or less, or an integer of 1 or less. For example, when M¹¹ is tin (Sn), the oxidation number of tin (Sn) may be trivalent or tetravalent, and thus the number of substituents (R⁹¹) that can be substituted for tin (Sn) (n⁹¹) may be an integer of 3 or 4. Therefore, n⁹¹ may be the same value as the oxidation number of M¹¹.

For example, the metal precursor may be represented by Chemical Formulas 9-1 to 9-4.

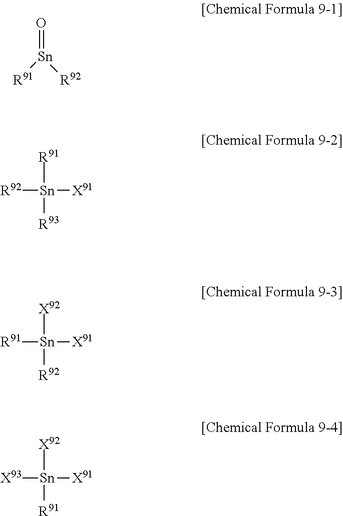

In Chemical Formulas 9-1 to 9-4, R⁹¹ to R⁹³ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof. More detailed descriptions therefor are the same as that described for R¹¹ in Chemical Formula 1, and thus repeated descriptions are omitted.

X⁹¹ to X⁹³ are each independently a halogen, and may be for example fluorine (F), chlorine (Cl), bromine (Br), or iodine (I).

The organic ligand may be represented by Chemical Formulas 11 to 25.

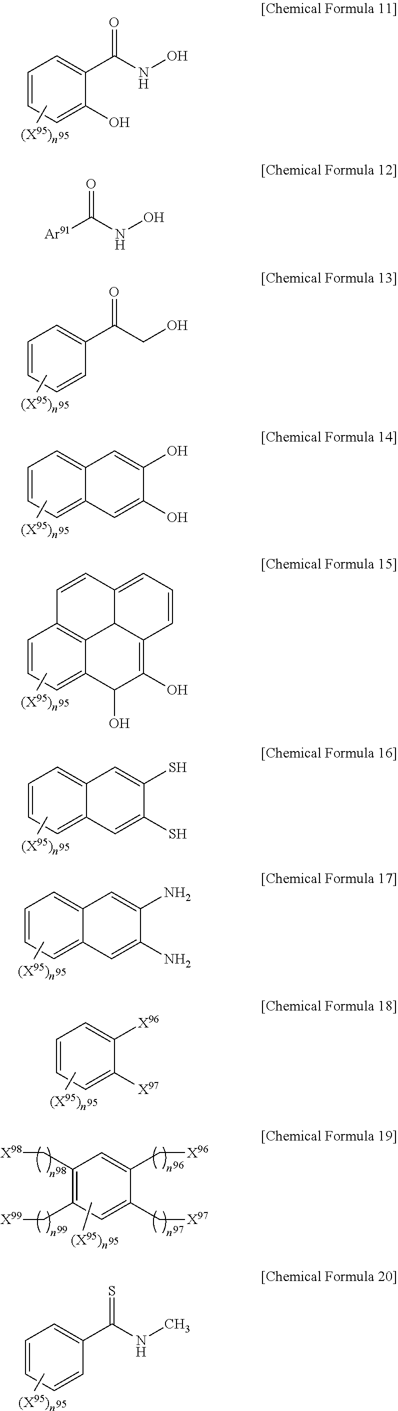

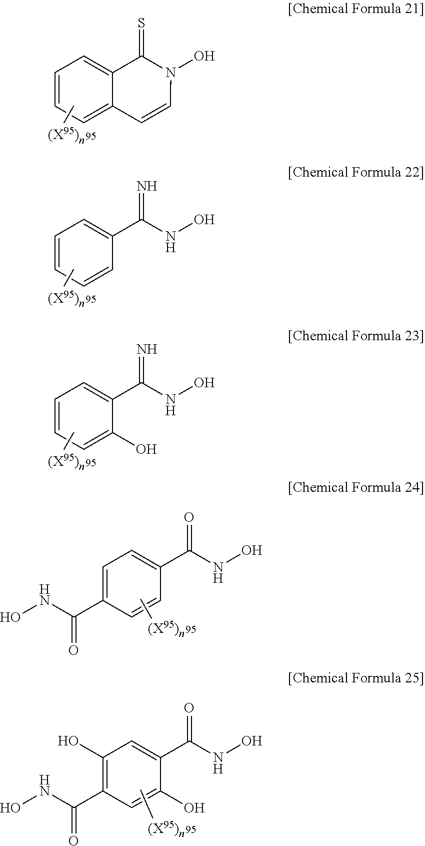

In Chemical Formula 12, Ar⁹¹ may be an aryl group, a heteroaryl group, or a combination thereof. Herein, the combination thereof may be, for example, biphenyl in which benzene and benzene are linked by a single bond, naphthalene in which benzene and benzene are fused, or phenyl furan in which furan is substituted with benzene.

In Chemical Formulas 11 to 25, X⁹⁶ to X⁹⁹ are each independently a substituent including OH, OR′, SH, SR′, or NRR′, wherein R and R′ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof.

X⁹⁵ is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, wherein, the combination thereof may include, for example, a hydroxyl-alkyl group in which an alkyl group and a hydroxy group are combined, an alkyl-aryl group in which an alkyl group and an aryl group are combined, a halogenated alkyl group in which an alkyl group is substituted with a halogen, or a hydroxyl-aryl group in which an aryl group is substituted with a hydroxy group, etc.

n⁹⁵ is the number of substitutable positions of the aromatic ring in which X⁹⁵ is substituted, and may be for example, an integer of 0 or more, an integer of 1 or more, an integer of 2 or more, an integer of 3 or more, an integer of 4 or more, an integer of 5 or more, an integer of 6 or more, an integer of 10 or more, an integer of 20 or more, or an integer of 30 or more, for example, an integer of 30 or less, an integer of 20 or less, an integer of 10 or less, an integer of 6 or less, an integer of 5 or less, an integer of 4 or less, an integer of 3 or less, an integer of 2 or less, or an integer of 1 or less. For example, in Chemical Formula 11, the aromatic ring is benzene, and thus subtracting the bonds with —C(═O)—NH—OH and —OH substituted in benzene, the total number (n⁹⁵) of substituents (X⁹⁵) that can be substituted in benzene may be 4 including a hydrogen group. n⁹⁶ to n⁹⁹ are each independently an integer of 1 to 8, for example, n⁹⁶ to n⁹⁹ are each independently are an integer of 1 to 4.

As an example, the organic ligand represented by Chemical Formula 11 may be represented by Chemical Formulas 11-1 to 11-15.

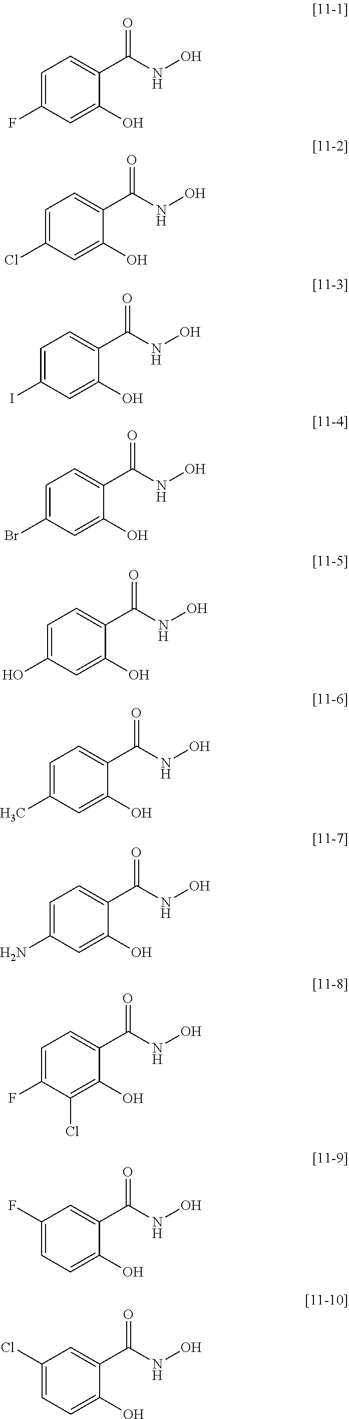

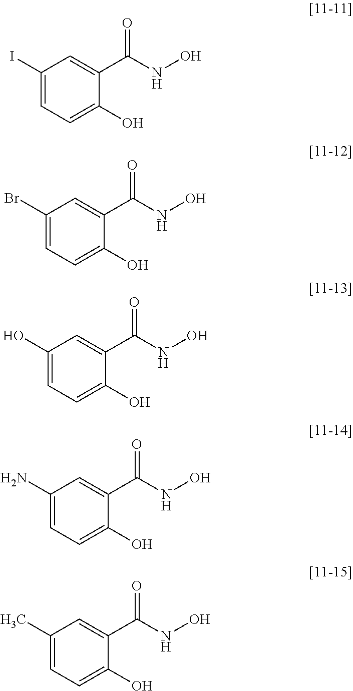

As an example, the organic ligand represented by Chemical Formula 12 may be represented by Chemical Formulas 12-1 to 12-28.

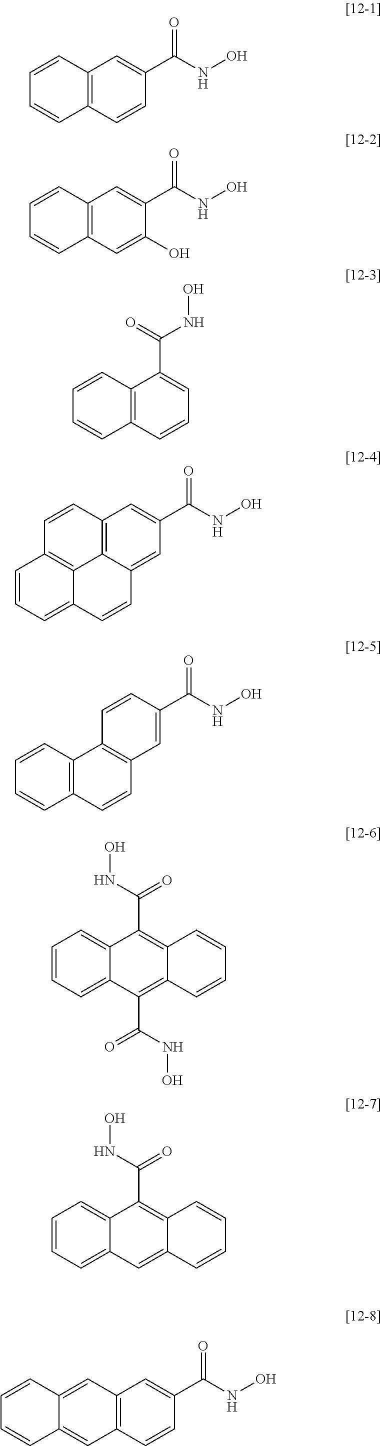

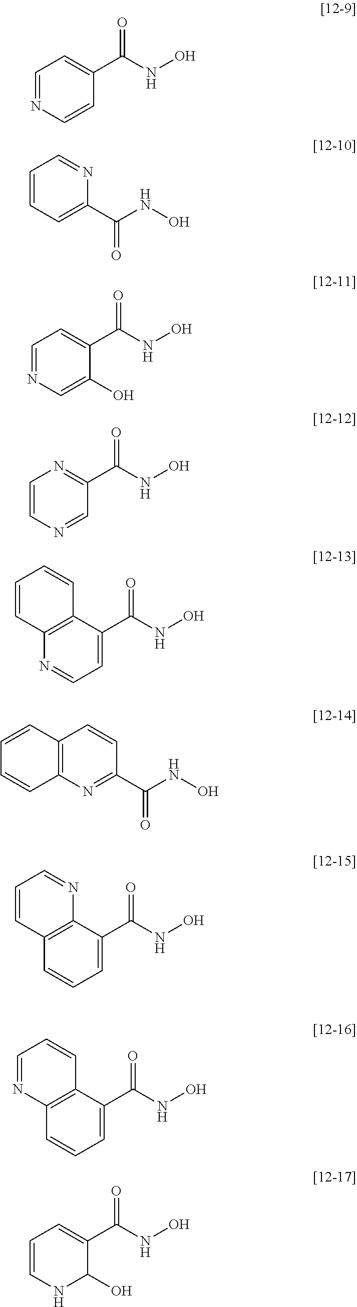

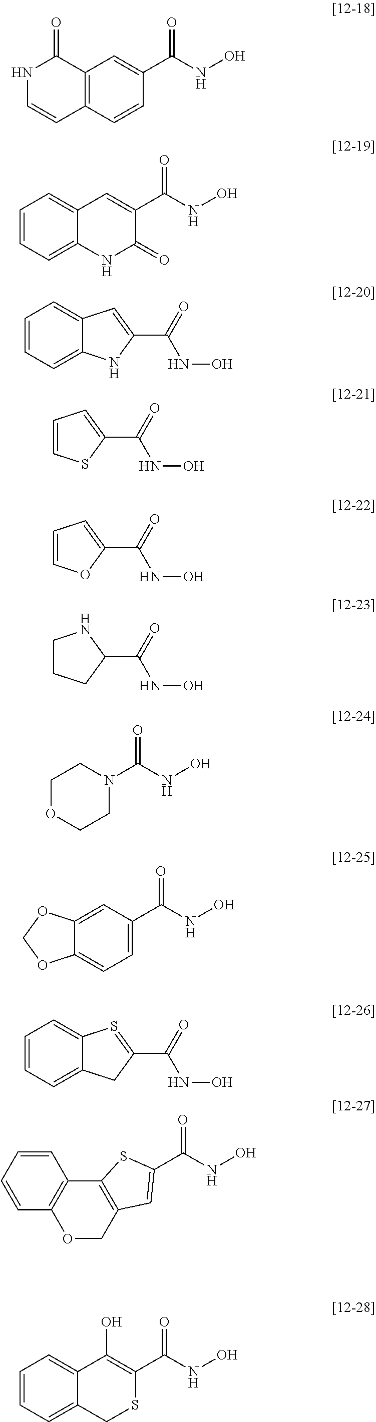

As an example, the organic ligand represented by Chemical Formula 13 may be represented by Chemical Formulas 13-1 to 13-6.

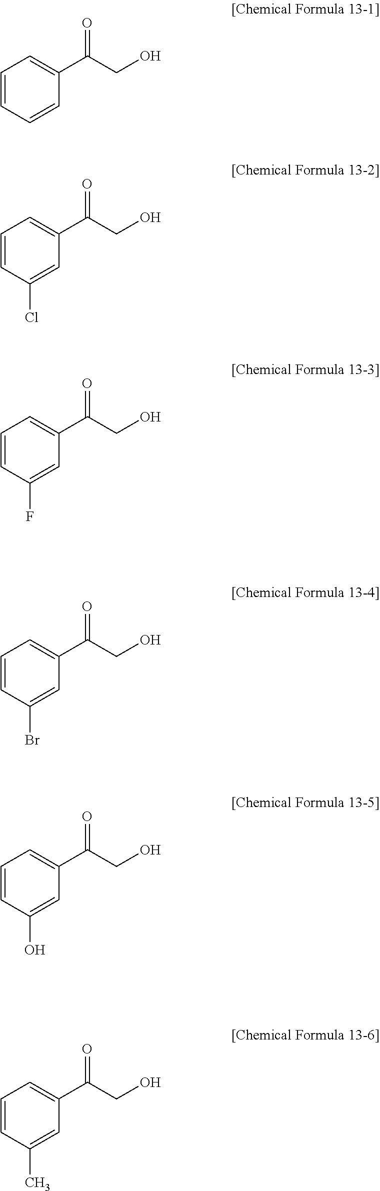

As an example, the organic ligand represented by Chemical Formulas 14 to 17 may be represented by Chemical Formulas 14-1 to 14-5.

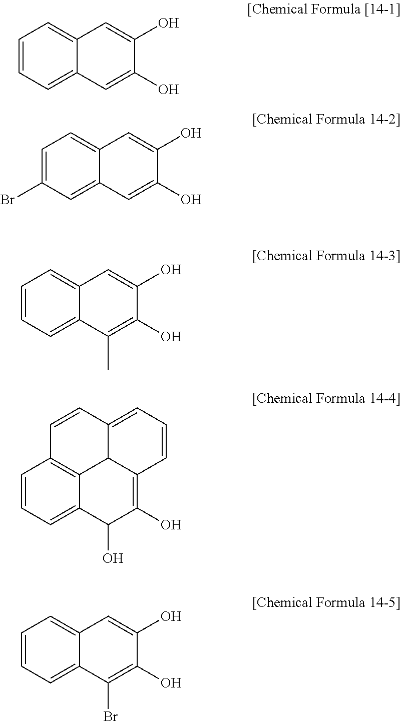 [SMILES: Oc1cc2ccccc2cc1O ; Oc1cc2ccc(Br)cc2cc1O ; Cc1c(O)c(O)cc2ccccc12 ; OC1=C2C=CC=C3C=Cc4cccc(c4C32)C1O ; Oc1cc2ccccc2c(Br)c1O]

As an example, the organic ligand represented by Chemical Formulas 18 and 19 may be represented by Chemical Formulas 18-1 to 18-31.

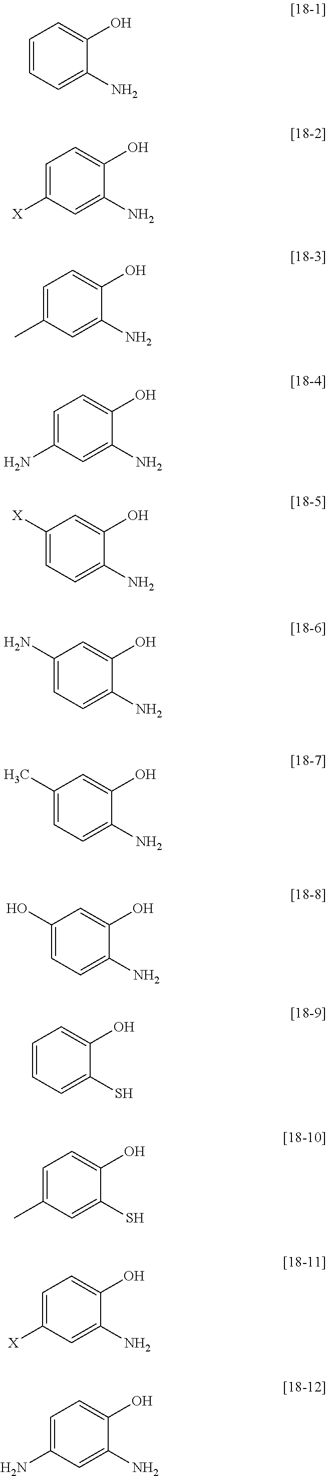

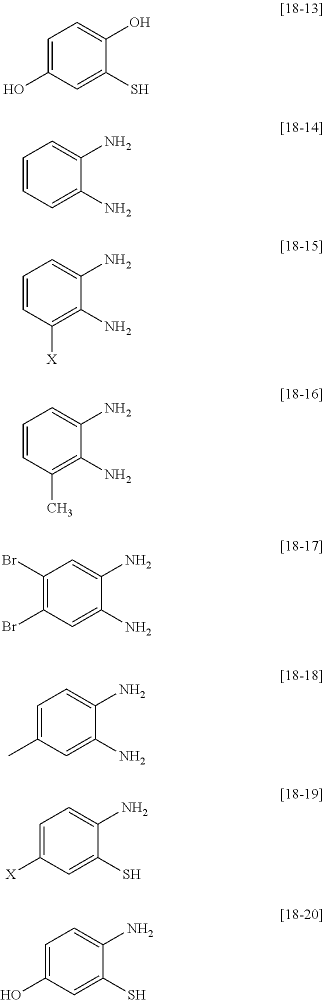

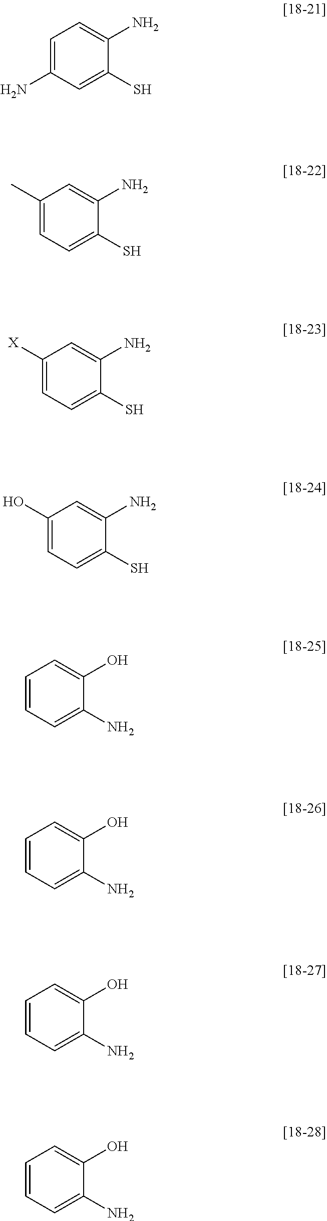

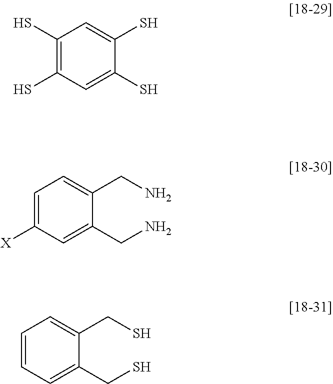

In Chemical Formulas 18-1 to 18-31, X may each independently be a halogen, and may be for example fluorine (F), chlorine (Cl), bromine (Br), or iodine (I).

As an example, the organic ligand represented by Chemical Formulas 20 to 23 may be represented by Chemical Formulas 20-1 to 20-15.

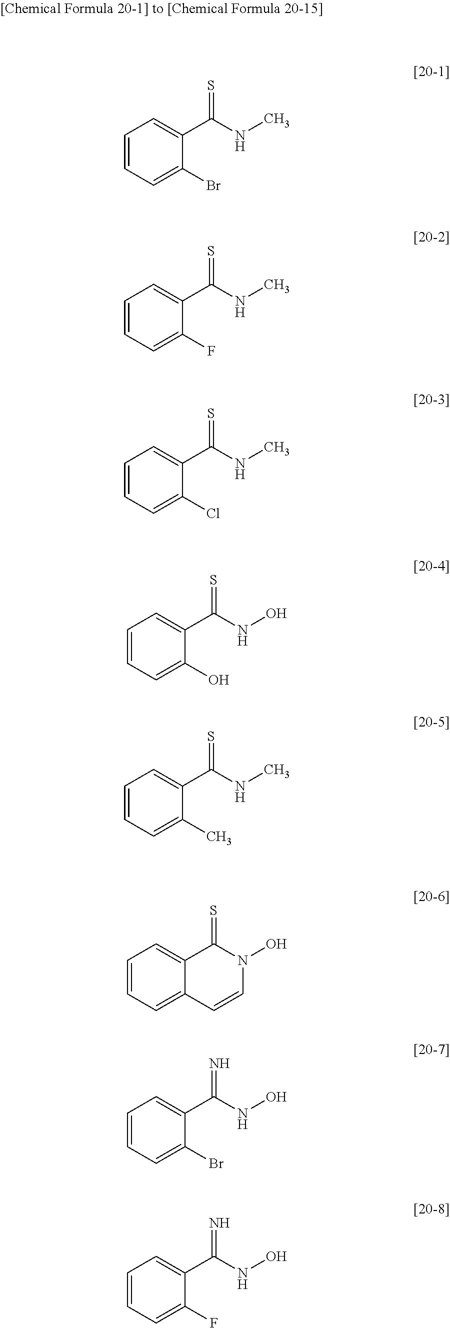

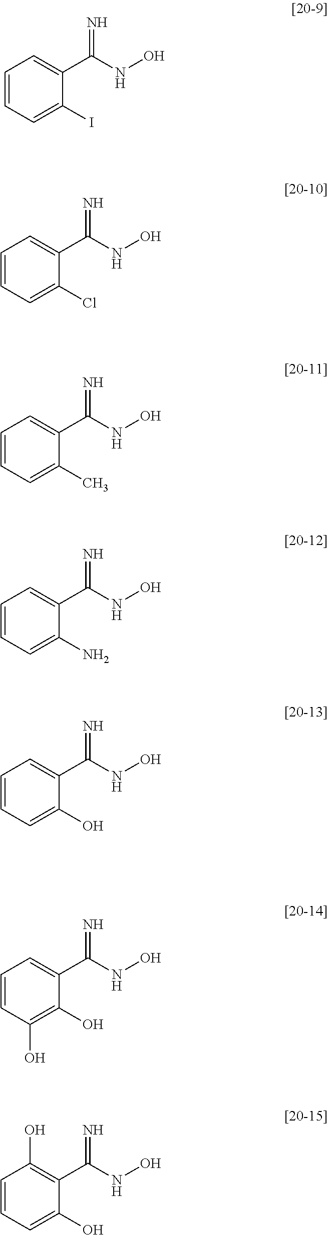

As an example, the organic ligand represented by Chemical Formulas 24 and 25 may be represented by Chemical Formulas 24-1 to 25-1.

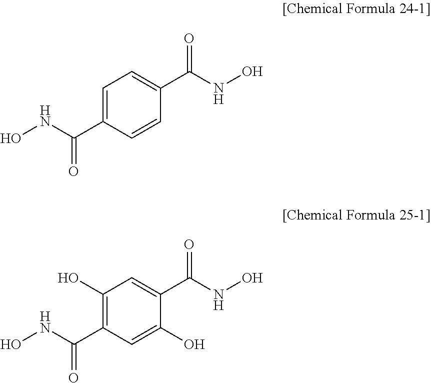 [SMILES: O=C(NO)c1ccc(C(=O)NO)cc1 ; O=C(NO)c1cc(O)c(C(=O)NO)cc1O]

Meanwhile, the organic ligands can be divided into organic ligands that form a 5-membered ring, organic ligands that form a 6-membered ring, or organic ligands that form a 7-membered ring, depend on the type of the ring they form by combining with a metal.

As an example, the organic ligand forming a 5-membered ring may be compounds represented by Group 1.

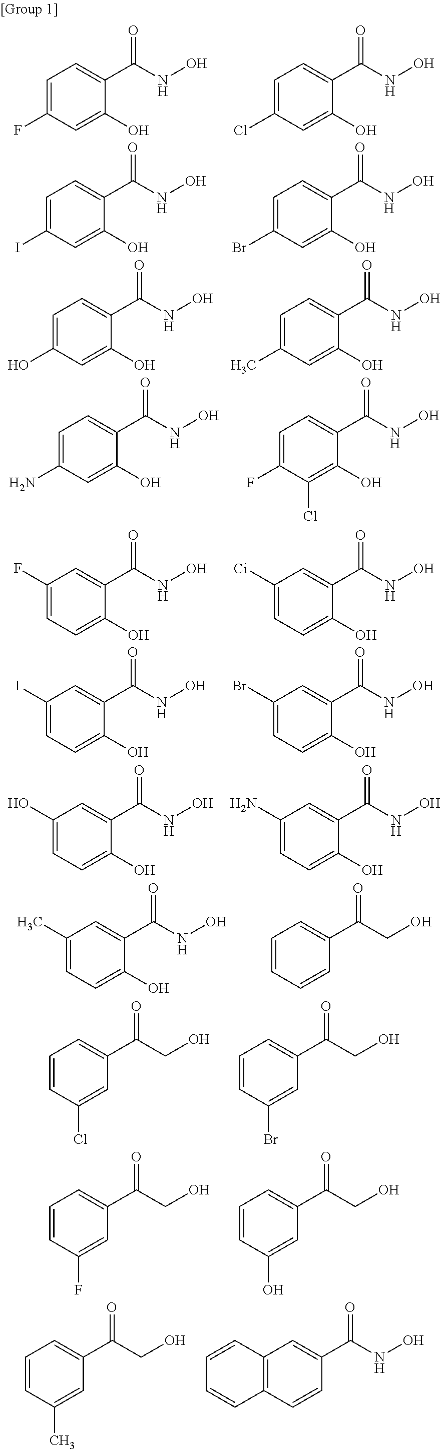

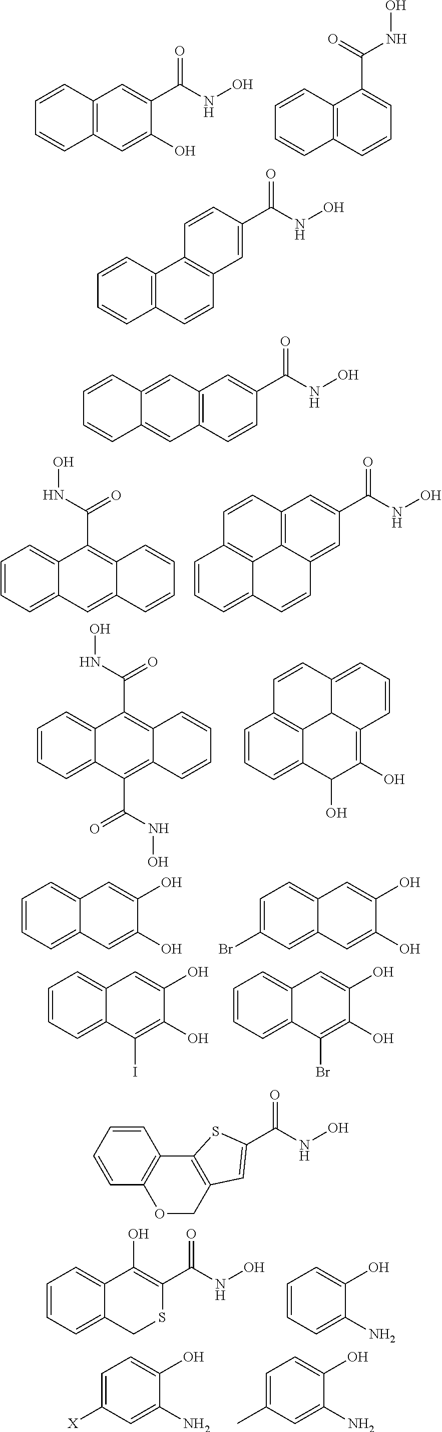

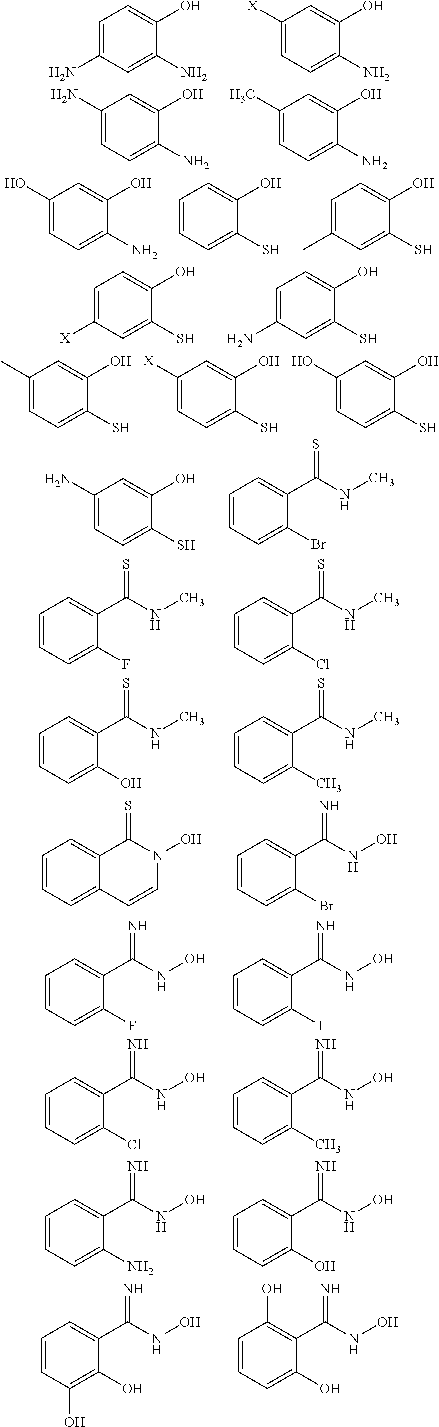

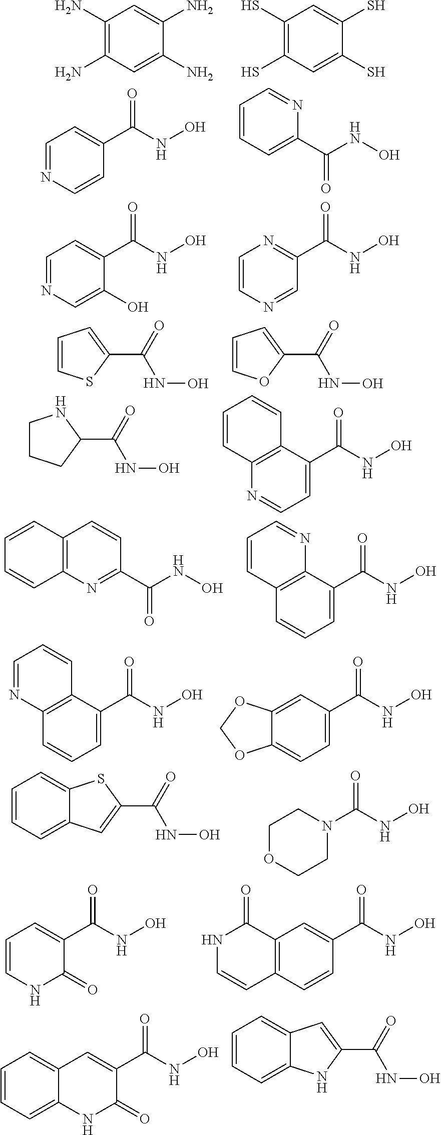

As an example, the organic ligand forming a 6-membered ring may be compounds represented by Group 2.

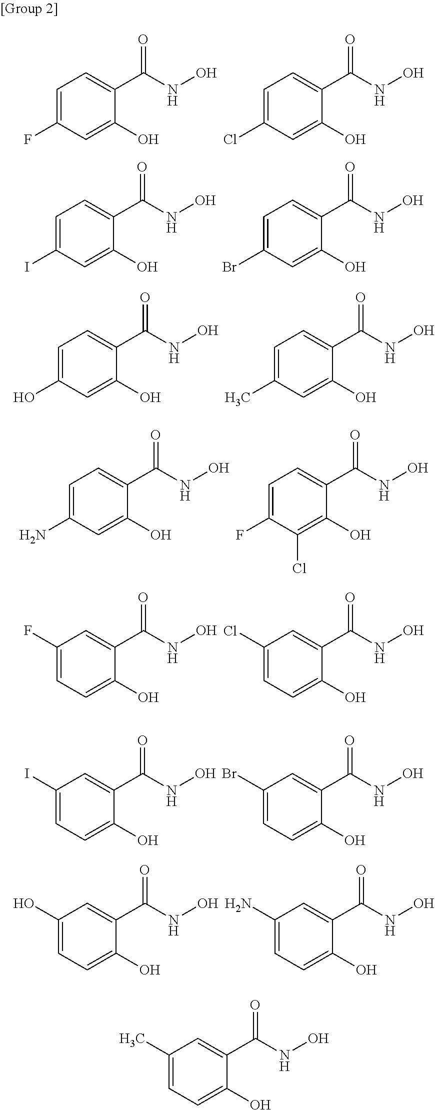

As an example, the organic ligand forming a 7-membered ring may be compounds represented by Group 3.

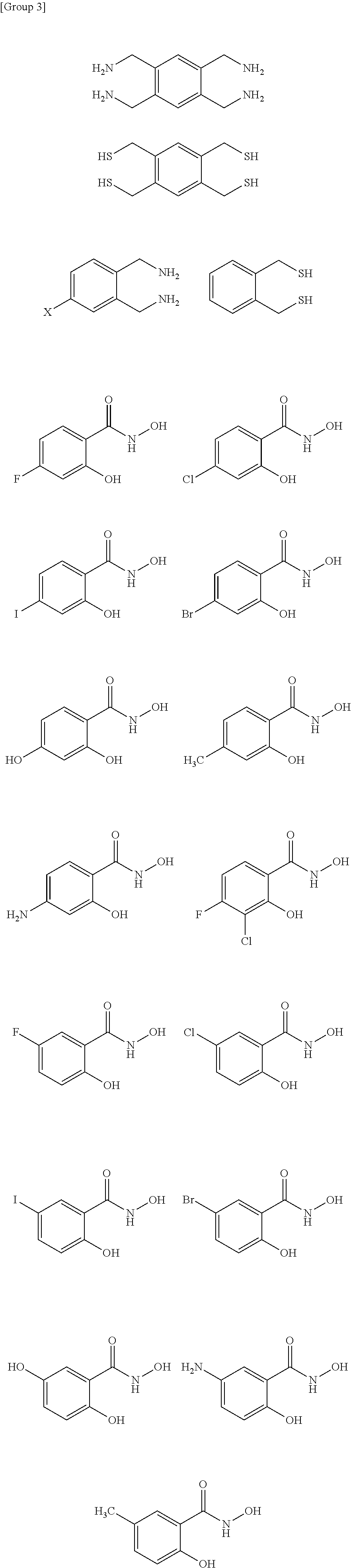

As described above, the organometallic compound can be formed by coordinating a metal precursor and an organic ligand, and the synthesized final product can be obtained by concentrating a solvent under reduced pressure.

The obtained organometallic compound can be recrystallized, and the recrystallization can be performed by heating the solvent and then cooling it. The recrystallization solvent may be methanol, ethanol, acetone, acetonitrile, ethyl acetate, toluene, hexane, or heptane.

As another recrystallization method, the product can be obtained by precipitation, in which generally precipitates may be obtained based on differences in solubility in the solvent. Suitable solvents for precipitation may include hydrocarbons (aliphatic hydrocarbons such as pentane, hexane, heptane, or octane; alicyclic hydrocarbons such as cyclohexane or methylcyclohexane; or aromatic hydrocarbons such as benzene, toluene, or xylene); halogenated hydrocarbons (aliphatic halogenated hydrocarbons such as methylene chloride, chloroform, or carbon tetrachloride; or aromatic halogenated hydrocarbons such as chlorobenzene or dichlorobenzene); nitro compounds (nitromethane or nitroethane, etc.); nitriles (such as acetonitrile or benzonitrile); ethers (chain ether such as diethyl ether, diisopropyl ether, or dimethoxyethane; or cyclic ether such as tetrahydrofuran or dioxane); ketones (such as acetone, methyl ethyl ketone, or diisobutyl ketone); esters (such as ethyl acetate or butyl acetate, etc.); carbonates (such as dimethyl carbonate, diethyl carbonate, ethylene carbonate, or propylene carbonate); alcohols (such as methanol, ethanol, propanol, isopropyl alcohol, or butanol); carboxylic acids (such as acetic acid, etc.); water; or any combination thereof, but is not limited thereto. The amount of precipitation or reprecipitation solvent used can be appropriately selected considering efficiency and yield.

The photoresist composition may include an organometallic compound in an amount of about 1 wt % to about 30 wt %, for example, about 1 wt % to about 25 wt %, about 1 wt % to about 20 wt %, about 1 wt % to about 15 wt %, about 1 wt % to about 10 wt %, or about 1 wt % to about 5 wt % based on the total weight. When the organometallic compound is included in this range, the storage stability and solubility characteristics of the photoresist composition can be improved, thin film formation can be facilitated, and sensitivity and resolution characteristics can be improved.

Meanwhile, as described above, the metal (M¹¹) of the organometallic compound provides an additional coordination bond site for the lone pair of electrons of the solvent in the solvent, and thus a cluster in which bonding between the organometallic compound and the solvent may be induced.

Compared to the general single molecule form, this cluster form satisfies the coordination number of the metal due to additional coordination bonds and structurally hides the metal atoms, and thereby can improve moisture stability and prevent aggregation due to condensation reaction after hydrolysis, which may result in increased long-term storage stability. Accordingly, defects are effectively reduced in the coating process, which can also affect coating stability.

In addition, in some embodiments, as the aggregation phenomenon is prevented, it can be coated in an amorphous form without the use of additives during spin coating, and thus sensitivity and coating properties can be improved.

Solvents included in the photoresist composition according to some embodiments may include aromatic compounds, alcohols, ethers, esters, ketones, naphtha, or combinations thereof.

The aromatic compounds may be, for example, benzene, xylene, or toluene.

The alcohols may be, for example, 4-methyl-2-pentanol, 4-methyl-2-propanol, 1-butanol, methanol, ethanol, isopropyl alcohol, 1-propanol, or butanol.

The ethers may be, for example, dimethoxymethane, diethyl ether, methyl-tert-butyl ether, anisole, tetrahydrofuran, 2-methyl tetrahydrofuran, cyclopentyl methyl ether, or dioxane.

The esters may be, for example, n-butyl acetate, propylene glycol monomethyl ether acetate, ethyl lactate, or ethyl acetate.

The ketones may be, for example, acetone, methyl ethyl ketone, or 2-heptanone.

Optionally, the photoresist composition may further include a photoinitiator.

The photoinitiator may be a PAG (photoacid generator) configured to generate an acid by light, a PRG (photoradical generator) configured to generate a radical by light, or a combination of PAG and PRG.

The PAG may generate acid when exposed to light from a KrF excimer laser (248 nm), ArF excimer laser (193 nm), F2 excimer laser (157 nm), or EUV laser (13.5 nm).

As an example, the PAG may include triarylsulfonium salts, diaryliodonium salts, sulfonates, or a mixture thereof. For example, the PAG may include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonate), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium PFOS, N-hydroxysuccinimide PFOS, norbornene-dicarboximide PFOS, or a mixture thereof.

For example, when PRG is exposed to light from a KrF excimer laser (248 nm), ArF excimer laser (193 nm), F2 excimer laser (157 nm), or EUV laser (13.5 nm), it absorbs light and generates radicals, thereby producing photochemical properties to initiate polymerization of the organometallic compound contained in the photoresist composition.

For example, PRG may include an acylphosphine oxide-based compound, an oxime ester-based compound, etc. The acylphosphine oxide compound may include, for example, 2,4,6-trimethylbenzoyl-diphenylphosphine oxide, bis(2,4,6-trimethylbenzoyl)-phenylphosphine oxide, or bis(2,6-dimethoxybenzoyl)-(2,4,4-trimethylpentyl)phosphine oxide, etc. The oxime ester compounds may include, for example, 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-9H-carbazol-3-yl]ethanone-1-(O-acetyl)oxime, 1-[9-ethyl-6-[2-methyl-4-[1-(2,2-dimethyl-1,3-dioxolane-4-yl)methyloxy]benzoyl]-9H-carbazol-3-yl]ethanone-1-(O-acetyl)oxime, and the like.

As an example, PRG may include commercially available products such as IRGACURE 651, IRGACURE 184, IRGACURE 1173, IRGACURE 2959, IRGACURE 127, IRGACURE 907, IRGACURE 369, IRGACURE 379, IRGACURE TPO, IRGACURE 819, IRGACURE OXE01, IRGACURE OXE02, IRGACURE MBF, or IRGACURE 754 (BASF product, brand name).

For example, the photoresist composition may include a photoinitiator in an amount of about 2 wt % to about 60 wt % based on a total weight, but is not limited thereto.

Optionally, the composition for semiconductor resist may further include additives.

For example, the additives may be a surfactant, a crosslinking agent, a leveling agent, a dispersant, an organic acid, a moisture absorbent, a coupling agent, a quencher, or any combination thereof.

The surfactant can play a role in improving the coating uniformity and wettability of the photoresist composition. As an example, the surfactant may include a sulfuric acid ester salt, a sulfonate salt, a phosphoric acid ester, soap, an amine salt, a quaternary ammonium salt, polyethylene glycol, an alkylphenol ethylene oxide adduct, a polyhydric alcohol, a nitrogen-containing vinyl polymer, or any combination thereof, but is not limited thereto. Additionally, the surfactant may include alkylbenzenesulfonate, an alkylpyridinium salt, polyethylene glycol, or a quaternary ammonium salt. When the photoresist composition includes a surfactant, the surfactant may be included in an amount of about 0.001 wt % to about 3 wt % based on a total weight of the photoresist composition.

The crosslinking agent may be, for example, a melamine-based crosslinking agent, a substituted urea-based crosslinking agent, an acrylic-based crosslinking agent, an epoxy-based crosslinking agent, or a polymer-based crosslinking agent. Additionally, crosslinking agents having at least two crosslinking substituents may include, for example, a compound such as methoxymethylated glycoluril, butoxymethylated glycoluril, methoxymethylated melamine, butoxymethylated melamine, methoxymethylated benzoguanamine, butoxymethylated benzoyl guanamine, 4-hydroxybutyl acrylate, acrylic acid, urethane acrylate, 1,4-butanediol diglycidyl ether, glycidol, diglycidyl 1,2-cyclohexane dicarboxyl Compounds, trimethylpropane triglycidyl ether, 1,3-bis(glycidoxypropyl)tetramethyldisiloxane, methoxymethylated urea, butoxymethylated urea, or methoxymethylated thiourea.

The leveling agent is intended to improve coating flatness during printing, and known leveling agents available commercially can be used.

The dispersant may serve to ensure that each component constituting the photoresist composition is uniformly dispersed within the photoresist composition. As an example, the dispersant may include an epoxy resin, polyvinyl alcohol, polyvinyl butyral, polyvinylpyrrolidone, glucose, sodium dodecyl sulfate, sodium citrate, oleic acid, linoleic acid, or any combination thereof, but is not limited to these. When the photoresist composition includes a dispersant, the dispersant may be included in an amount of about 0.001 wt % to about 5 wt % based on a total weight of the photoresist composition.

The organic acid may include p-toluenesulfonic acid, benzenesulfonic acid, p-dodecylbenzenesulfonic acid, 1,4-naphthalenedisulfonic acid, methanesulfonic acid, malonic acid, citric acid, propionic acid, methacrylic acid, oxalic acid, lactic acid, glycolic acid, succinic acid, or any combination thereof, but is not limited thereto.

The moisture absorbent can play a role in preventing adverse effects caused by moisture in the photoresist composition. For example, the moisture absorbent may include polyoxyethylene nonylphenolether, polyethylene glycol, polypropylene glycol, polyacrylamide, or any combination thereof, but is not limited thereto. When the photoresist composition includes a moisture absorbent, the moisture absorbent may be included in an amount of about 0.001 wt % to about 10 wt % based on a total weight of the photoresist composition.

The coupling agent may serve to improve adhesion to the resist underlayer film when coating the photoresist composition on the resist underlayer film. As an example, the coupling agent may include a silane coupling agent. For example, the silane coupling agent may include vinyltrimethoxysilane, vinyltriethoxysilane, vinyl trichlorosilane, vinyltris(p-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane, but is not limited thereto. When the photoresist composition includes a coupling agent, the coupling agent may be included in an amount of about 0.001 wt % to about 5 wt % based on a total weight of the photoresist composition.

The quencher may be methyl diphenyl amine, triphenyl amine, phenylenediamine, naphthylamine, diaminonaphthalene, or any combination thereof.

In the photoresist composition, when the solvent consists only of an organic solvent, the photoresist composition may further include water. In this case, the water content may be about 0.001 wt % to about 0.1 wt % based on a total weight of the photoresist composition.

The photoresist composition may not cause pattern collapse even if a pattern with a high aspect ratio is formed. Thus, in order to form a micropattern with a width of about 5 nm to about 100 nm, for example a micropattern with a width of about 5 nm to about 80 nm, a micropattern with a width of about 5 nm to about 70 nm, a micropattern with a width of about 5 nm to about 50 nm, a micropattern with a width of about 5 nm to about 40 nm, a micropattern with a width of about 5 nm to about 30 nm, or a micropattern with a width of about 5 nm to about 20 nm, a photolithography process using light with a wavelength of about 5 nm to about 150 nm, for example, a photolithography process using light with a wavelength of about 5 nm to about 100 nm, a photolithography process using light with a wavelength of about 5 nm to about 80 nm, a photolithography process using light with a wavelength of about 5 nm to about 50 nm, a photolithography process using light with a wavelength of about 5 nm to about 30 nm, or a photolithography process using light with a wavelength of about 5 nm to about 20 nm may be used.

According to another embodiment, a method of forming patterns using the above-described photoresist composition may be provided.

A method of forming patterns according to some embodiments includes forming a film to be etched on a substrate, forming a photoresist film by applying the aforementioned photoresist composition on the film to be etched, patterning the photoresist film to form a photoresist pattern, and etching the film to be etched using the photoresist pattern as an etching mask.

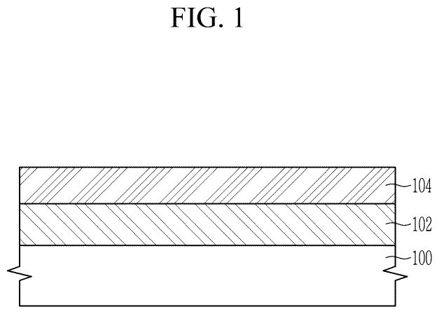

Hereinafter, with reference to FIGS. 1 to 5, a method of forming patterns using the above-described photoresist composition will be described. FIGS. 1 to 5 are cross-sectional views showing intermediate steps of the method of forming a pattern.

Referring to FIG. 1, first, an object to be etched is prepared.

As an example, the object to be etched may be a thin film 102 formed on the semiconductor substrate 100.

As an example, the substrate 100 may include a semiconductor substrate, and the thin film 102 may be an insulating film, a conductive film, or a semiconductor film. For example, the thin film 102 may include a metal, an alloy, metal carbide, metal nitride, metal oxynitride, metal oxycarbide, semiconductor, polysilicon, oxide, nitride, oxynitride, or a combination, but is not limited thereto.

Optionally, the surface of the thin film 102 may be cleaned to remove contaminants remaining on the thin film 102.

Additionally, optionally, a resist underlayer film 104 may be formed on the surface of the thin film 102.

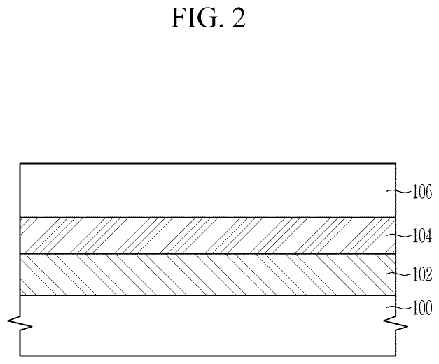

The resist underlayer film 104 is formed between the substrate 100 and the photoresist film 106 shown in FIG. 2, which will be described later, and when radiation reflected from the interface between the substrate 100 and the photoresist film 106 or from the interlayer hardmask is scattered into an unintended photoresist area, it is possible to prevent non-uniformity of the photoresist linewidth and interference with pattern formation.

As an example, a composition for forming a resist underlayer film 104 is applied on the surface of the cleaned thin film 102 by spin coating, spray coating, dip coating, knife edge coating, or inkjet printing. After coating by applying a printing method such as screen printing, drying and baking processes can be performed to form a resist underlayer film 104 on the thin film 102. The baking treatment can be carried out between about 100° C. and about 500° C., for example between about 100° C. and about 300° C.

As an example, the resist underlayer film 104 may include an organic or inorganic anti-reflective coating (ARC) material for a KrF excimer laser, an ArF excimer laser, an EUV laser, or any other light source. For example, the resist underlayer film 104 may include a bottom anti-reflective coating (BARC) layer or a developable bottom anti-reflective coating (DBARC) layer. Additionally, the resist underlayer film 104 may include an organic component having a light absorption structure. The light absorbing structure may be, for example, a hydrocarbon compound having one or more benzene rings or a structure in which benzene rings are fused. The resist underlayer film 104 may be formed to have a thickness of about 1 nm to about 100 nm, but is not limited thereto.

Referring to FIG. 2, the aforementioned photoresist composition is coated on the resist underlayer film 104 to form a photoresist film 106.

As an example, the photoresist film 106 is formed by applying the aforementioned photoresist composition to the substrate 100 on which the thin film 102 is formed, using spin coating, spray coating, dip coating, or knife edge coating method, or by applying the aforementioned photoresist composition using a printing method such as inkjet printing, screen printing, and then drying the applied photoresist composition. That is, the photoresist film 106 may be formed by coating the aforementioned photoresist composition on the thin film 102 formed on the substrate 100 and then curing it through a heat treatment process.

Next, a first baking process of heating the substrate 100 on which the photoresist film 106 is formed may be performed. The first baking process may be performed at a temperature of about 80° C. to about 180° C. for about 30 seconds to about 3 minutes.

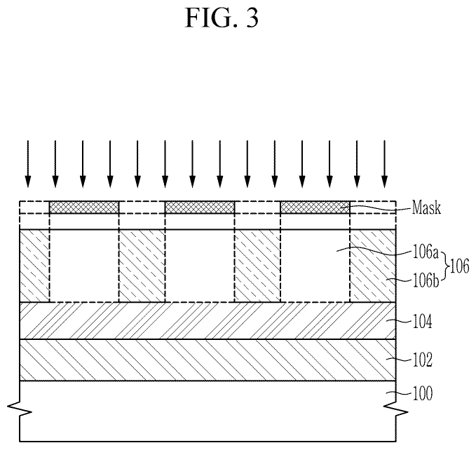

Referring to FIG. 3, the photoresist film 106 is selectively exposed.

For example, examples of light that can be used in the exposure process may include light with a high energy wavelength such as EUV (Extreme UltraViolet; wavelength 13.5 nm) or E-Beam (electron beam) as well as light with short wavelengths such as activating radiation i-line (wavelength 365 nm), KrF excimer laser (wavelength 248 nm), and ArF excimer laser (wavelength 193 nm). For example, the exposure light may be short-wavelength light having a wavelength range of about 5 nm to about 150 nm, and may be light having a high-energy wavelength such as EUV or E-Beam.

The exposed region 106b of the photoresist film 106 has a different solubility from the unexposed region 106a of the photoresist film 106 as a polymer is formed through a crosslinking reaction such as condensation between organometallic compounds.

Subsequently, a second baking process may be performed on the substrate 100. The second baking process may be performed at a temperature of about 120° C. to about 200° C. for about 30 seconds to about 3 minutes. By performing the second baking process, the exposed region 106b of the photoresist film 106 becomes difficult to dissolve in the developer.

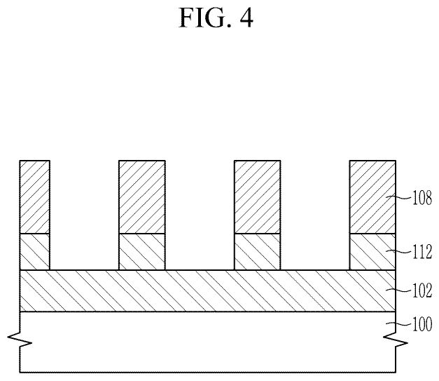

Referring to FIG. 4, the photoresist film 106 corresponding to the unexposed region 106a is dissolved and removed using a developer to form a photoresist pattern 108. As an example, the photoresist film 106 corresponding to the unexposed region 106a is dissolved using an organic solvent such as 2-heptanone and then removed to create a photoresist pattern 108 corresponding to a negative tone image.

As an example, the developer may be an organic solvent, for example, ketones such as methyl ethyl ketone, acetone, cyclohexanone, and 2-heptanone, alcohols such as methanol, 4-methyl-2-propanol, 1-butanol, isopropanol, and 1-propanol, or esters such as propylene glycol monomethyl ether acetate, ethyl acetate, ethyl lactate, n-butyl acetate, butyrolactone, or aromatic compounds such as benzene, xylene, and toluene, or any combination thereof. Additionally, the developer may be an organic solvent containing about 9 wt % or less of an acidic or basic substance based on the total weight.

However, the pattern forming method according to some embodiments is not limited to forming a negative tone image, and may be formed to have a positive tone image. In this case, the developer that can be used to form a positive tone image may be, for example, a quaternary ammonium hydroxide composition, such as tetraethylammonium hydroxide, tetrapropylammonium hydroxide, tetrabutylammonium hydroxide, or any combination thereof.

The photoresist pattern 108 formed by the pattern forming method may have a width of about 5 nm to about 100 nm, for example about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

Additionally, the photoresist pattern 108 may have a pitch having a half-pitch of about 50 nm or less, for example, about 40 nm or less, about 30 nm or less, about 20 nm or less, about 15 nm or less, about 10 nm or less, about 5 nm or less, and having a line width roughness of about 3 nm or less, or about 2 nm or less.

Next, the resist underlayer film 104 is etched using the photoresist pattern 108 as an etch mask, thereby forming the organic film pattern 112. The organic film pattern 112 may also have a width corresponding to the photoresist pattern 108 described above.

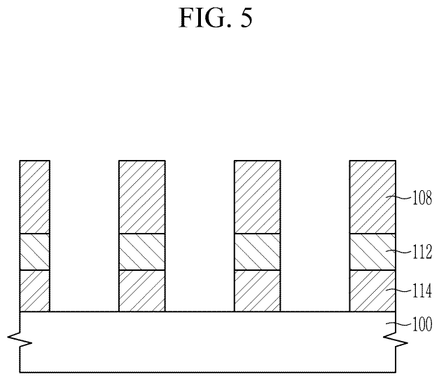

Referring to FIG. 5, the photoresist pattern 108 is applied as an etch mask to etch the exposed thin film 102 to form a thin film pattern 114.

As an example, the etching of the thin film 102 may be performed by wet etching or dry etching. In the case of dry etching, an etching gas containing, for example, CHF₃, CF₄, Cl₂, BCl₃, or a mixture thereof may be used.

The thin film pattern 114 may have a width corresponding to the photoresist pattern 108. As an example, the thin film pattern 114 may have a width of about 5 nm to about 100 nm, for example, about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In addition, the thin film pattern 114 may have a pitch having a half-pitch of about 50 nm or less, for example, about 40 nm or less, 30 nm or less, about 20 nm or less, about 15 nm or less, about 10 nm or less, or about 5 nm or less, and a linewidth roughness of about 3 nm or less, or about 2 nm or less.

Hereinafter, the present embodiment will be described in more detail through examples related to the production of the aforementioned photoresist composition. However, the technical features of the present embodiment are not limited to the following examples.

### Preparation Example 1: Synthesis of Organometallic Compounds

### Synthesis Example 1

In a 250 mL round-bottomed flask, 0.3 g (1.82 mmol) of dimethyl tin oxide, a metal precursor, is dispersed in 100 mL of toluene, 0.285 g (1.86 mmol) of salicylhydroxamic acid, an organic ligand, is added thereto, and then, a reflux device is inststalled thereto to substitute an internal gas with nitrogen gas. After stirring the mixture at 180° C. for 3 hours, a solid compound is obtained therefrom by removing the solvent under a reduced pressure and washing it with methanol to obtain a compound represented by Chemical Formula 4-1-2, C₂₇H₃₃N₃O₉Sn₃, with a yield of 65%.

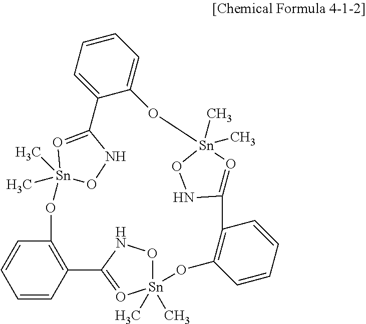

### Synthesis Example 2

In a 250 mL round-bottomed flask, 0.3 g (1.21 mmol) of dimethyl tin oxide, a metal precursor, is dispersed in 100 mL of methanol, 0.185 g (1.21 mmol) of salicylhydroxamic acid, an organic ligand, is added thereto, and then, a reflux device is installed thereto to substitute an internal gas with nitrogen gas. After stirring the mixture at 120° C. for 3 hours, the following viscous fluid is obtained therefrom by removing the solvent under a reduced pressure and dissolved in toluene and then, filtered through Celite® and concentrated to obtain a red viscous fluid represented by Chemical Formula 6-1-2 with a yield of 70%.

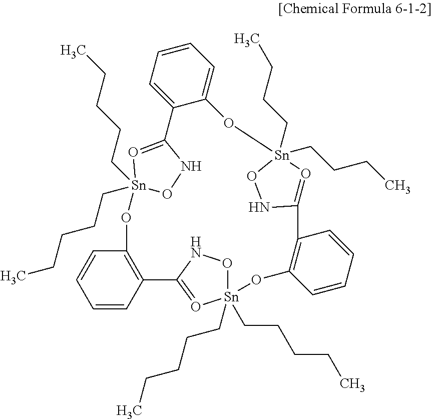

### Synthesis Examples 3 to 19

Each organometallic compound is synthesized in the same manner as in Synthesis Example 1 or Synthesis Example 2 by changing types of the metal precursor and the organic ligand as shown in Table 1.

TABLE 1

| | | Metal | |
|---|---|---|---|
| | Organic ligand | precursor | Organometallic compound |
| Synthesis Example 3 | 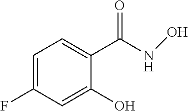 [SMILES: O=C(NO)c1ccc(F)cc1O] | Chemical Formula 9-1, Chemical Formula 9-3 | 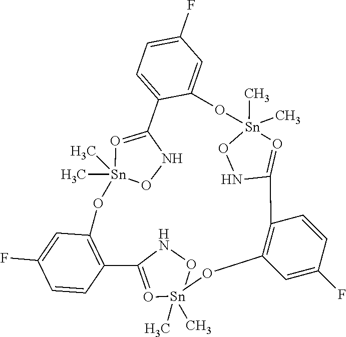 |
| Synthesis Example 4 | 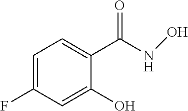 [SMILES: O=C(NO)c1ccc(F)cc1O] | Chemical Formula 9-2 | 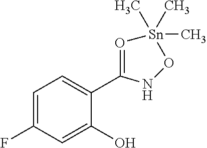 |
| Synthesis Example 5 | 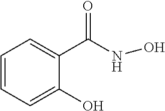 [SMILES: O=C(NO)c1ccccc1O] | Chemical Formula 9-4 | 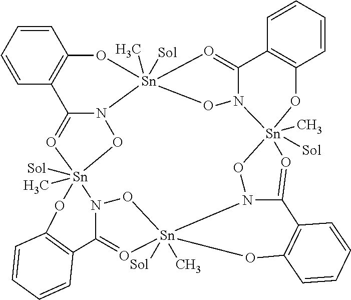 |
| Synthesis Example 6 | 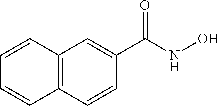 [SMILES: O=C(NO)c1ccc2ccccc2c1] | Chemical Formula 9-2 | 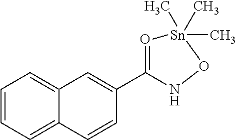 |
| Synthesis Example 7 | 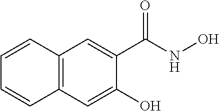 [SMILES: O=C(NO)c1cc2ccccc2cc1O] | Chemical Formula 9-2 | 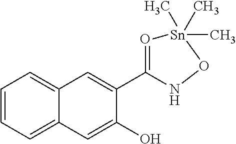 |
| Synthesis Example 8 | 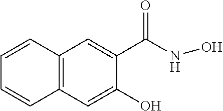 [SMILES: O=C(NO)c1cc2ccccc2cc1O] | Chemical Formula 9-1, Chemical Formula 9-3 | 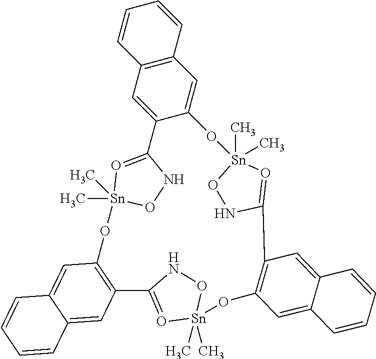 |
| Synthesis Example 9 | 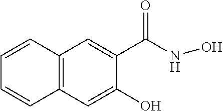 [SMILES: O=C(NO)c1cc2ccccc2cc1O] | Chemical Formula 9-4 | 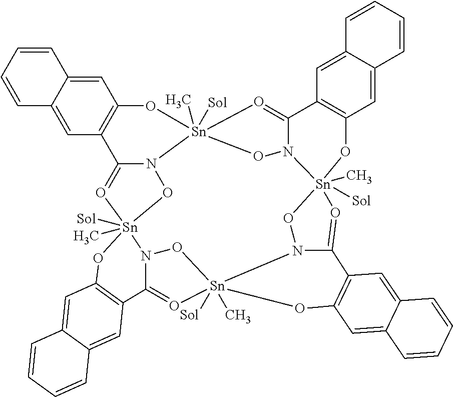 |
| Synthesis Example 10 | 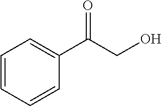 | Chemical Formula 9-2 | 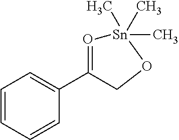 |
| Synthesis Example 11 | 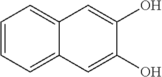 [SMILES: Oc1cc2ccccc2cc1O] | Chemical Formula 9-1, Chemical Formula 9-3 | 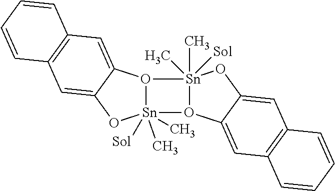 |
| Synthesis Example 12 | 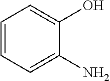 | Chemical Formula 9-1, Chemical Formula 9-3 | 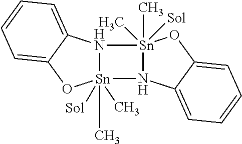 |
| Synthesis Example 13 | 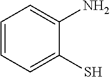 | Chemical Formula 9-1, Chemical Formula 9-3 | 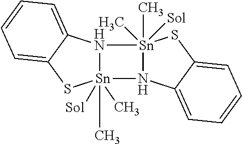 |
| Synthesis Example 14 | 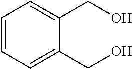 | Chemical Formula 9-1, Chemical Formula 9-3 | 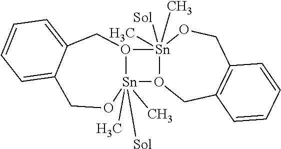 |
| Synthesis Example 15 | 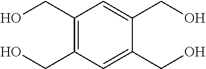 [SMILES: OCc1cc(CO)c(CO)cc1CO] | Chemical Formula 9-1, Chemical Formula 9-3 | 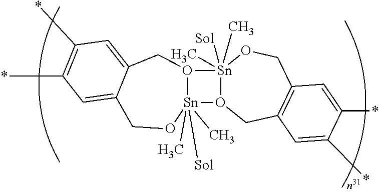 |
| Synthesis Example 16 | 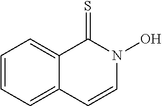 [SMILES: On1ccc2ccccc2c1=S] | Chemical Formula 9-2 | 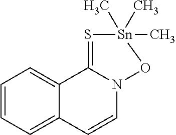 |
| Synthesis Example 17 | 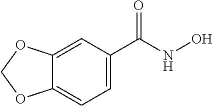 [SMILES: O=C(NO)c1ccc2c(c1)OCO2] | Chemical Formula 9-2 | 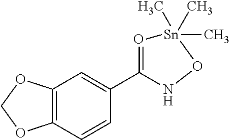 |
| Synthesis Example 18 | 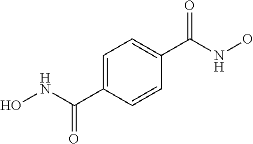 [SMILES: O=C(NO)c1ccc(C(=O)NO)cc1] | Chemical Formula 9-2 | 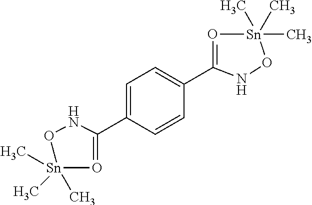 |
| Synthesis Example 19 | 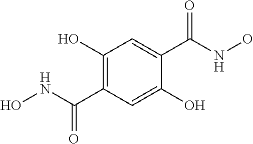 [SMILES: O=C(NO)c1cc(O)c(C(=O)NO)cc1O] | Chemical Formula 9-2 | polymer or cluster |

### Experimental Example 1: Evaluation of Organometallic Compounds

Each of the organometallic compounds according to Synthesis Examples 1 to 19 is examined with respect to a molecule structure by using NMR, JR spectroscopy, and X-ray diffraction and then, analyzed with respect to thermal properties by using a thermogravimetric analyzer.

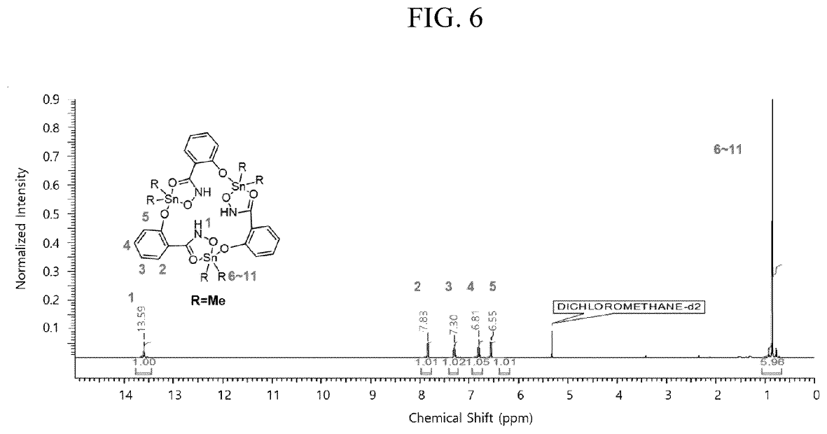

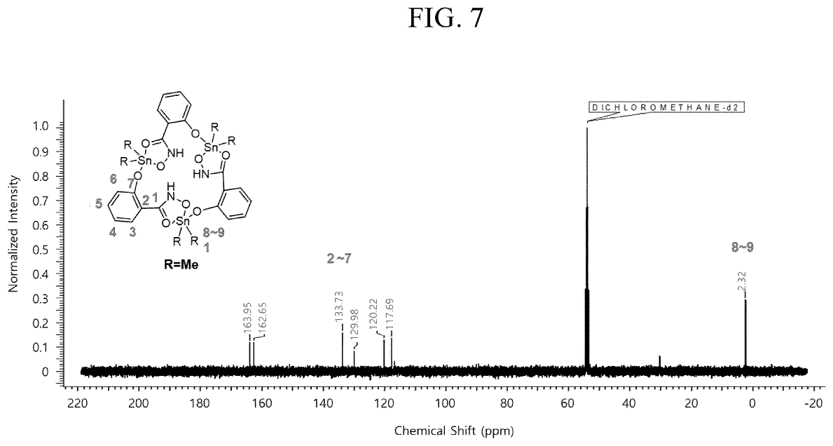

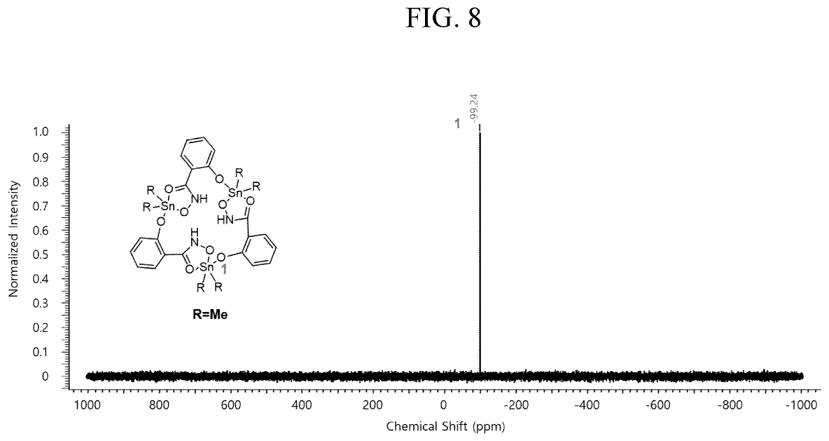

FIGS. 6 to 8 show the NMR spectroscopy spectrum result of the organometallic compound prepared in Synthesis Example 1, which are respectively proton NMR, ¹³C NMR, and ¹¹⁹Sn NMR results.

Referring to FIGS. 6 to 8, the proton NMR shows that a —NH peak appears at very deshielded 13.59 ppm, which indicates a binding interaction with tin. In addition, a ¹¹⁹Sn NMR peak appearing at −99.24 ppm corresponds to a range of a commonly occurring alkoxy tin peak, which indicates an Sn—O bond.

In addition, the organometallic compound of Synthesis Example 1 turns out to have a chemical formula of C₂₇H₃₃N₃O₉Sn₃ through the XRD structure analysis, which is a supramolecules structure that three C₉H₁₁NO₃Sn's form a ring.

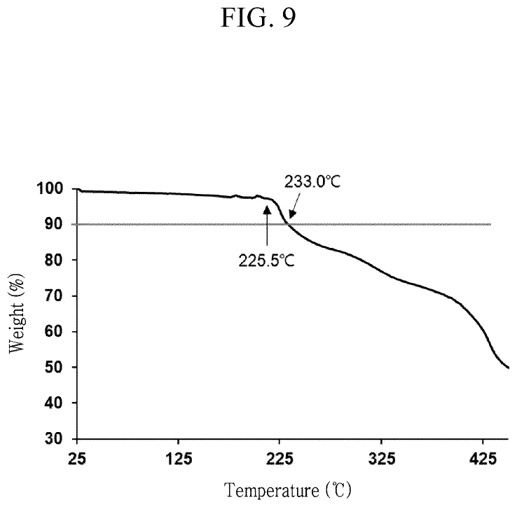

Furthermore, FIG. 9 is a graph showing the thermogravimetric analysis result of the organometallic compound according to Synthesis Example 1, which shows that the organometallic compound has 233° C. of a decomposition temperature reaching 90% of its mass and thus is very stable against heat.

### Preparation Example 2: Synthesis of Photoresist Composition

### Examples 1 to 19

Each of the organometallic compounds of Synthesis Examples 1 to 19 is dissolved in toluene at a weight ratio of 2 wt % and then, filtered with a 0.2 μm polytetrafluoroethylene (PTFE) syringe filter to prepare a photoresist composition.

### Experimental Example 2: Evaluation of Photoresist Compositions

### (Evaluation 1: UV Experiment)

Each of the photoresist compositions of Examples 1 to Example 19 is tested for photoreactivity to UV. For example, each of the toluene solutions is spin-coated on a bare Si wafer, but a portion thereof is exposed to UV of 254 nm for 2 hours.

As a result, it can be seen that the photoresist compositions of Examples 1 to Example 19 exhibit selective solubility to ethyl acetate (EA), toluene, and propylene glycol methyl ether acetate (PGMEA), depending on the exposure.

### (Evaluation 2: Electron Beam Experiment)

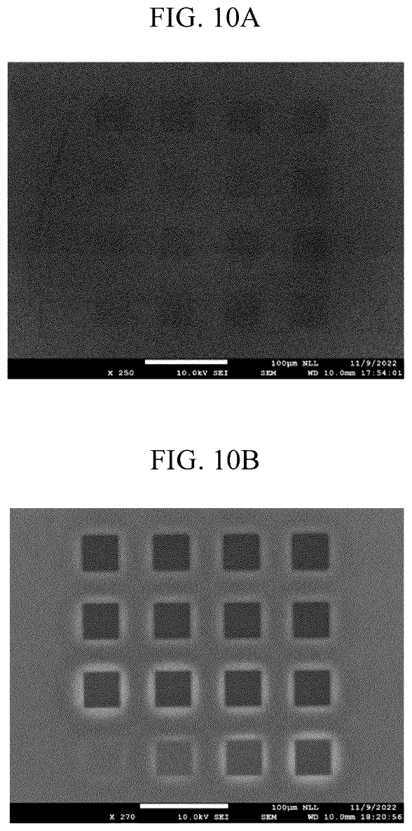

Each of the photoresist compositions of Example 1 to Example 19 is tested for photoreactivity to electron beams. For example, the test proceeds in 16 steps by starting from 50 μC/cm² and increasing it by 50 μC/cm², and FIGS. 10A-10B show a scanning electron microscope (SEM) photograph before and after the exposure.

In FIGS. 10A-10B, FIG. 10A is a scanning electron microscope photograph before the exposure, and FIG. 10B is a scanning electron microscope photograph after the exposure. A change before and after the exposure, as shown in FIGS. 10A-10B, confirms reactivity to the electron beams.

### (Evaluation 3: EUV Experiment)

Each of the photoresist compositions of Example 1 to Example 19 is tested for photoreactivity to EUV. For example, the photoresist composition is spin-coated at 3000 rpm for 30 seconds by using a circular silicon wafer having a native-oxide surface and a diameter of 4 inches as a thin film coating substrate. The coated composition is baked (or, additionally post-apply baked (PAB)) at 100° C. for 90 seconds to form a photoresist thin film.

After the coating and baking, a thickness of the film, when measured through ellipsometry, is 44 nm.

On the circular silicon wafer, the photoresist thin film formed from the coating is exposed to an extreme ultraviolet ray to form a line/space pattern of 8 nm to 50 nm by changing energy and a focus. After the exposure, the film is baked at 180° C. for 90 seconds and subsequently, dipped in propylene glycol methyl ether acetate for 30 seconds and taken out therefrom. Finally, the film is baked at 150° C. for 5 minutes.

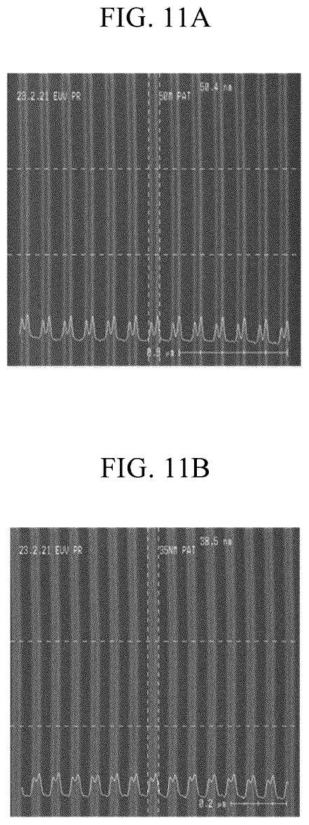

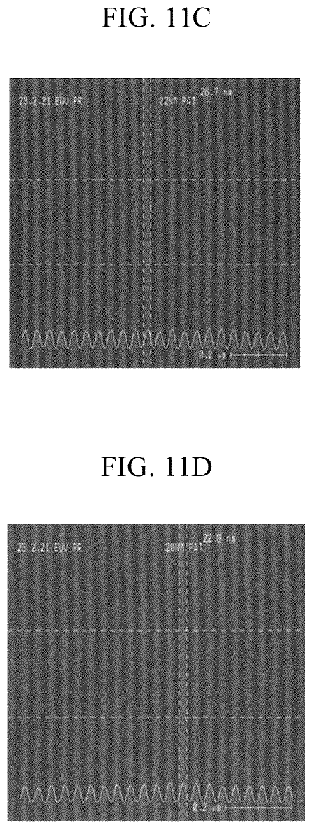

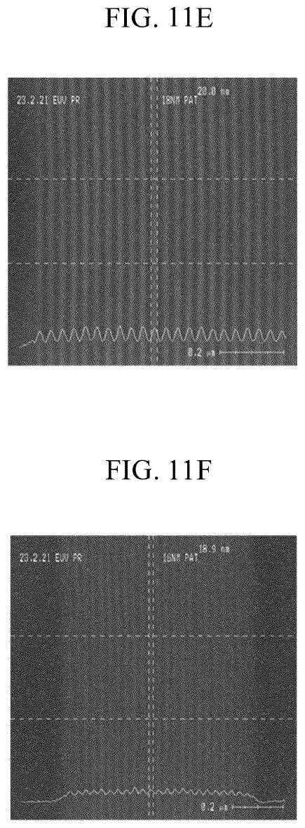

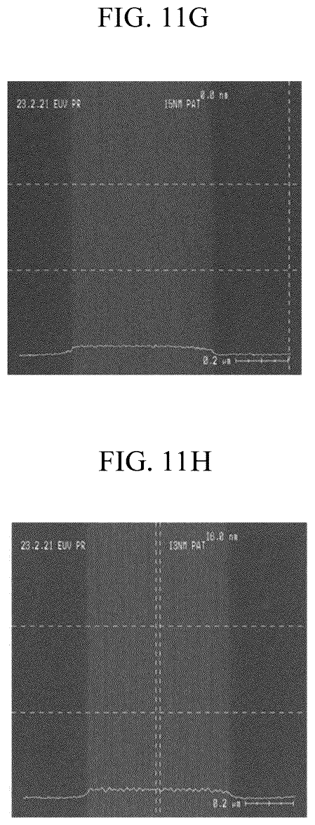

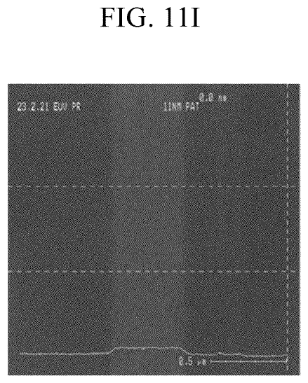

Referring to the ultraviolet (UV) exposure results, since the highest result is obtained at energy of 132.3 mJ/cm² and a focus of −20 nm, a size of each line/space (L/S) pattern area in a horizontal direction is measured at the energy of 132.3 mJ/cm² and the focus of −20 nm, and the results are shown in FIGS. 11A-11I and Table 2.

FIGS. 11A-11I include CD-SEM photographs showing after-development-inspection (ADI) results of the patterns in each area, wherein FIGS. 11A-11I show each 50P100, 35P70, 22P44, 20P40, 18P36, 16P32, 15P30, 13P26, and 11P22 result. Herein, 50P100, for example, shows a line width of 50 nm and a pitch of 100 nm (i.e., a space width of 50 nm).

Table 2 summarizes actual pattern width measurements in each area of and line edge roughness (LER) at each left and the right side in the ADI results in each region of the pattern.

TABLE 2

| | Measurement | LER (nm) |
|---|---|---|
| Feature | (nm) | (left/right) |
| 50P100 | 50.4 | 1.4/1.5 |
| 45P90 | 44.8 | 1.7/2.7 |
| 40P80 | 44.6 | 1.2/1.2 |
| 35P70 | 38.5 | 1.5/1.9 |
| 30P60 | 50 | 1.5/1.9 |
| 28P56 | 30.2 | 1.7/1.7 |
| 26P52 | 32.9 | 1.1/1.4 |
| 24P48 | 30.1 | 1.9/1.9 |
| 22P44 | 26.7 | 1.9/1.3 |
| 20P40 | 22.8 | 1.2/1.1 |
| 18P36 | 20.0 | —/— |
| 16P32 | 18.9 | —/— |
| 15P30 | NG | —/— |
| 14P28 | NG | —/— |
| 13P26 | NG | —/— |
| 11P22 | NG | —/— |

Referring to FIGS. 11A-11I and Table 2, the pattern of the 20P40 region may achieve LER ≤1.2 nm, and 16P32 may be the lowest resolution region where the pattern is transferable (definable). The pattern of the 20P40 region may achieve LWR ≤5 nm or less, or LWR ≤2 nm or less.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

<Description of Symbols>

| | |
|---|---|
| 100: substrate | 102: thin film |
| 104: resist underlayer film | 106: photoresist film |
| 106b: exposed region | 106a: unexposed region |
| 108: photoresist pattern | 112: organic film pattern |
| 114: thin film pattern | |

What is claimed is:

1. A photoresist composition, comprising:
an organometallic compound including
a ring including a metal, a first heteroatom coordinated to the metal, and a second heteroatom covalently bonded to the metal, and
an aromatic ring substituted or fused to the ring; and
a solvent.

2. The photoresist composition of claim 1, wherein
the organometallic compound is represented by Chemical Formula 1: 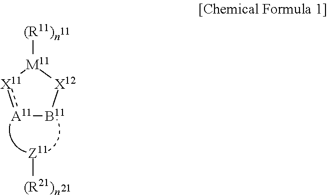
wherein, in Chemical Formula 1,
M¹¹ is the metal selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
X¹¹ and X¹² are each independently selected from O, S, or NR′,
A¹¹ and B¹¹ are each independently a linking group comprising a single bond, double bond, alkylene group, O, S, NR′, NHC(═O), SO, SO₂, CO, O—CO—O, C(═O)O, OCO, or any combination thereof,
Z¹¹ is the aromatic ring substituted for A¹¹, or Z¹¹ is a linking group including a single bond, double bond, alkylene group, O, S, NR′, NHC(═O), SO, SO₂, CO, O—CO—O, C(═O)O, OCO, or any combination thereof that is fused to A¹¹ and B¹¹ to form the aromatic ring,
R¹¹ and R²¹ are each independently a substituent including a hydrogen, a hydroxy group, a halogen, an alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹¹ is a solvent coordinated to M¹¹, or R¹¹ and R²¹ are each independently a linking group including a single bond, a double bond, an alkylene group, O, S, NR′, NHC(═O), SO, SO₂, CO, O—CO—O, C(═O)O, OCO, or any combination thereof,
R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof,
n¹¹ is a number of substitutable positions of M¹¹, and
n²¹ is a number of substitutable positions of the aromatic ring.

3. The photoresist composition of claim 2, wherein
the organometallic compound is represented by Chemical Formula 2: 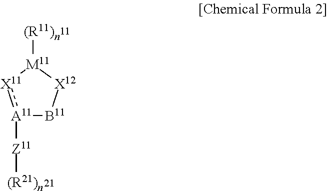
wherein, Z¹¹ is the aromatic ring substituted for A¹¹.

4. The photoresist composition of claim 3, wherein
the organometallic compound is represented by Chemical Formula 2-1 or 2-2: 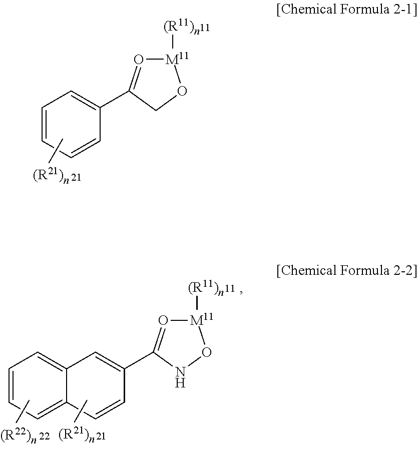
wherein, in Chemical Formula 2-2, R²² is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or a linking group including a single bond, a double bond, an alkylene group, O, S, NR′, NHC(═O), SO, SO₂, CO, O—CO—O, C(═O)O, OCO, or any combination thereof, and n²² is an integer of 4.

5. The photoresist composition of claim 2, wherein
the organometallic compound is represented by Chemical Formula 3:

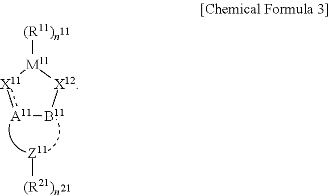

6. The photoresist composition of claim 5, wherein
the organometallic compound is represented by Chemical Formula 3-1:

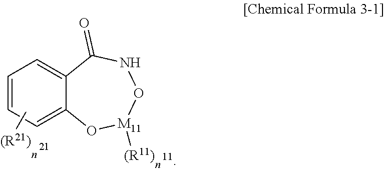

7. The photoresist composition of claim 1, wherein
the organometallic compound is represented by Chemical Formula 4: 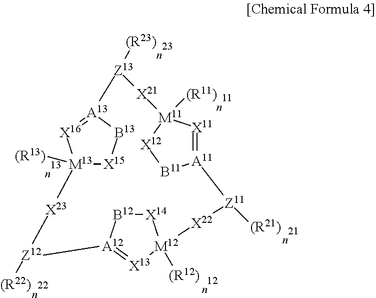
wherein, in Chemical Formula 4,
M¹¹ to M¹³ are each independently metals selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
X¹¹ to X¹⁶ are each independently selected from O, S, or NR′,
A¹¹ to A¹³, B¹¹ to B¹³, and X²¹ to X²³ are each independently a linking group including a single bond, a double bond, an alkylene group, O, S, NR′, NHC(═O), SO, SO₂, CO, O—CO—O, C(═O)O, OCO, or any combination thereof,
Z¹¹ to Z¹³ are each independently the aromatic ring substituted for A¹¹ to A¹³,
R¹¹ to R¹³ and R²¹ to R²³ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹¹ to R¹³ are a solvent coordinated to M¹¹ to M¹³, respectively,
R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof,
n¹¹ to n¹³ are each independently a number of substitutable positions for each of M¹¹ to M¹³; and
n²¹ to n²³ are each independently a number of substitutable positions for each of Z¹¹ to Z¹³.

8. The photoresist composition of claim 7, wherein
the organometallic compound is represented by Chemical Formula 4-1:

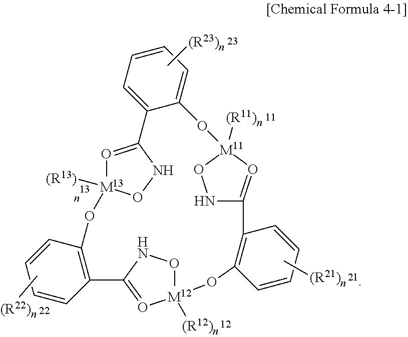

9. The photoresist composition of claim 2, wherein
the organometallic compound is represented by Chemical Formula 5: 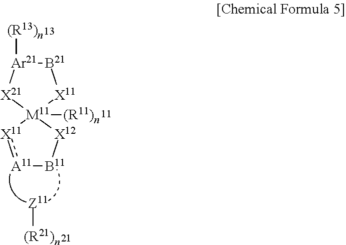
wherein, in Chemical Formula 5,
X²¹, and X²² are each independently selected from O, S, or NR′,
B²¹ is a linking group selected from a single bond, a double bond, an alkylene group, O, S, NR′, NHC(═O), SO, SO₂, CO, O—CO—O, C(═O)O, OCO, or any combination thereof,
Ar²¹ is an aromatic ring substituted for X²¹ and B²¹,
R¹³ is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹³ and R²¹ are each independently a linking group including a single bond, a double bond, an alkylene group, O, S, NR′, NHC(═O), SO, SO₂, CO, O—CO—O, C(═O)O, OCO, or any combination thereof,
n¹³ is the number of substitutable positions of Ar²¹.

10. The photoresist composition of claim 2, wherein
the organometallic compound represented by Chemical Formula 6: 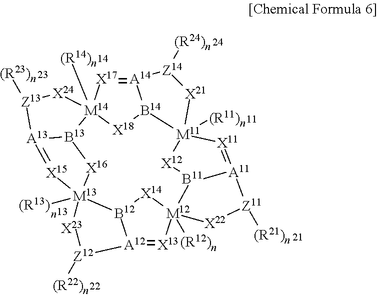
wherein, in Chemical Formula 6,
M¹¹ to M¹⁴ are each independently metals selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
X¹¹ to X¹⁸ are each independently selected from O, S, or NR′,
A¹¹ to A¹⁴, B¹¹ to B¹⁴, and X²¹ to X²⁴ are each independently a linking group including a single bond, a double bond, an alkylene group, O, S, NR′, NHC(═O), SO, SO₂, CO, O—CO—O, C(═O) O, OCO, or any combination thereof,
Z¹¹ to Z¹⁴ are each independently the aromatic rings substituted for A¹¹ to A¹⁴ and X¹¹ to X¹⁴,
R¹¹ to R¹⁴ and R²¹ to R²⁴ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹¹ to R¹⁴ are a solvent coordinated to one or more of M¹¹ to M¹⁴ respectively,
R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof,
n¹¹ to n¹⁴ are each independently a number of substitutable positions of each of M¹¹ to M¹⁴, respectively, and
n²¹ to n²⁴ are each independently a number of substitutable positions of each of Z¹¹ to Z¹⁴, respectively.

11. The photoresist composition of claim 10, wherein
the organometallic compound is represented by Chemical Formula 6-1:

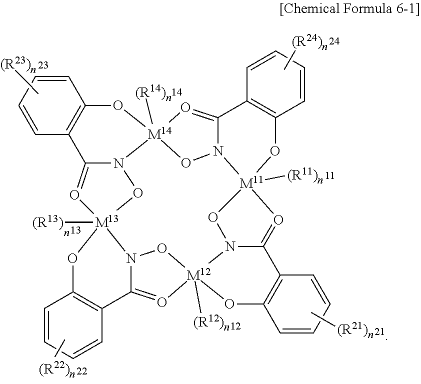

12. The photoresist composition of claim 2, wherein
the organometallic compound is represented by Chemical Formula 7: 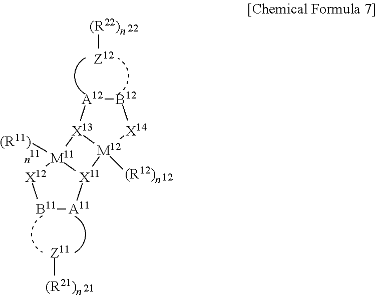
wherein, in Chemical Formula 7,
M¹¹ and M¹² are each independently a metal selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
X¹¹ to X¹⁴ are each independently selected from O, S, or NR′,
A¹¹, A¹², B¹¹, and B¹² are each independently a linking group including a single bond, a double bond, an alkylene group, O, S, NR′, NHC(═O), SO, SO₂, CO, O—CO—O, C(═O)O, OCO, or any combination thereof,
Z¹¹ and Z¹² are each independently the aromatic ring substituted for A¹¹ and A¹², or Z¹¹ and Z¹² are each independently linking groups including a single bond, a double bond, an alkylene group, O, S, NR′, NHC(═O), SO, SO₂, CO, O—CO—O, C(═O)O, OCO, or any combination thereof that is fused to A¹¹ and B¹¹ or A¹² and B¹² to form the aromatic ring,
R¹¹ and R¹² are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹¹ and R¹² are a solvent coordinated to each of M¹¹ and M¹² respectively,
R²¹ and R²² are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or the R²¹ and R²² are each independently a linking group including a single bond, a double bond, an alkylene group, O, S, NR′, NHC(═O), SO, SO₂, CO, O—CO—O, C(═O)O, OCO, or any combination thereof,
n¹¹ and n¹² are each independently a number of substitutable positions of each of M¹¹ and M¹², respectively, and
n²¹ and n²² are each independently a number of substitutable positions of each of Z¹¹ and Z¹², respectively.

13. The photoresist composition of claim 12, wherein
the organometallic compound is represented by Chemical Formulas 7-1 to 7-3:

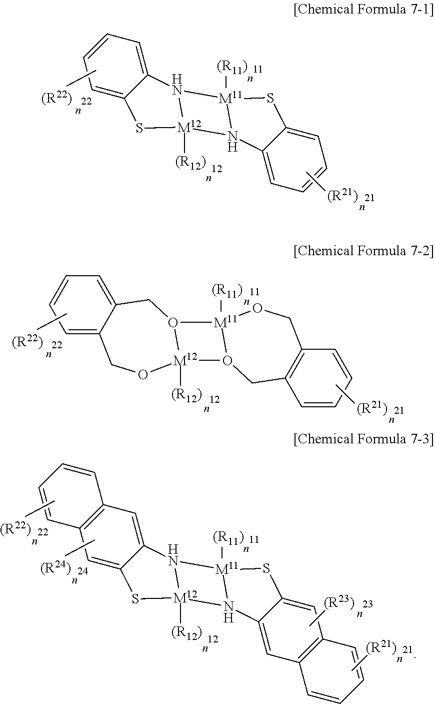

14. The photoresist composition of claim 2, wherein
the organometallic compound is represented by Chemical Formula 8: 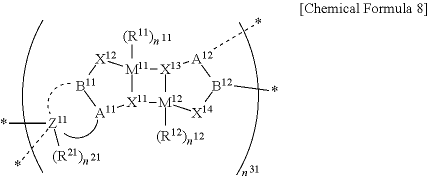
wherein, in Chemical Formula 8,
M¹¹ and M¹² are each independently a metal selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
X¹¹ to X¹⁴ are each independently selected from O, S, or NR′,
A¹¹, A¹², B¹¹, and B¹² are each independently a linking group including a single bond, a double bond, an alkylene group, O, S, NR′, NHC(═O), SO, SO₂, CO, O—CO—O, C(═O)O, OCO, or any combination thereof,
Z¹¹ is a linking group including a single bond, double bond, alkylene group, O, S, NR′, NHC(═O), SO, SO₂, CO, O—CO—O, C(═O)O, OCO, or any combination thereof that is fused to A¹¹, B¹¹, A¹², and B¹² to form an aromatic ring,
R¹¹, R¹², and R²¹ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹ and R¹² are solvents coordinated to M¹¹ and M¹² respectively,
n¹¹ and n¹² are each independently a number of substitutable positions of each of M¹¹ and M¹², respectively,
n²¹ is a number of substitutable positions of Z¹¹, and
n³¹ is an integer of 1 to 100.

15. The photoresist composition of claim 14, wherein
the organometallic compound is represented by Chemical Formula 8-1: 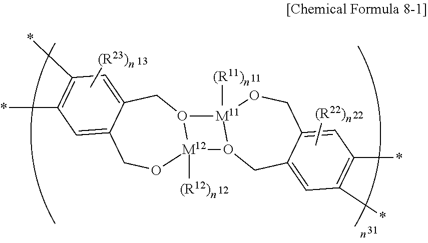
wherein n¹³ and n²² are integers of 2,
R²² and R²³ are a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof.

16. The photoresist composition of claim 1, wherein
the organometallic compound is formed by coordinating a metal precursor including the metal and an organic ligand including the aromatic ring in which the first and second heteroatoms bonded with the metal are substituted,
the metal precursor is represented by Chemical Formula 9, and
the organic ligand is represented by one of Chemical Formulas 11 to 25: 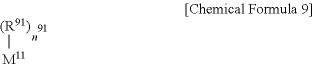
wherein, in Chemical Formula 9,
M¹¹ is the metal selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
R⁹¹ is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, and
n⁹¹ is a number of substitutable positions of M¹¹, 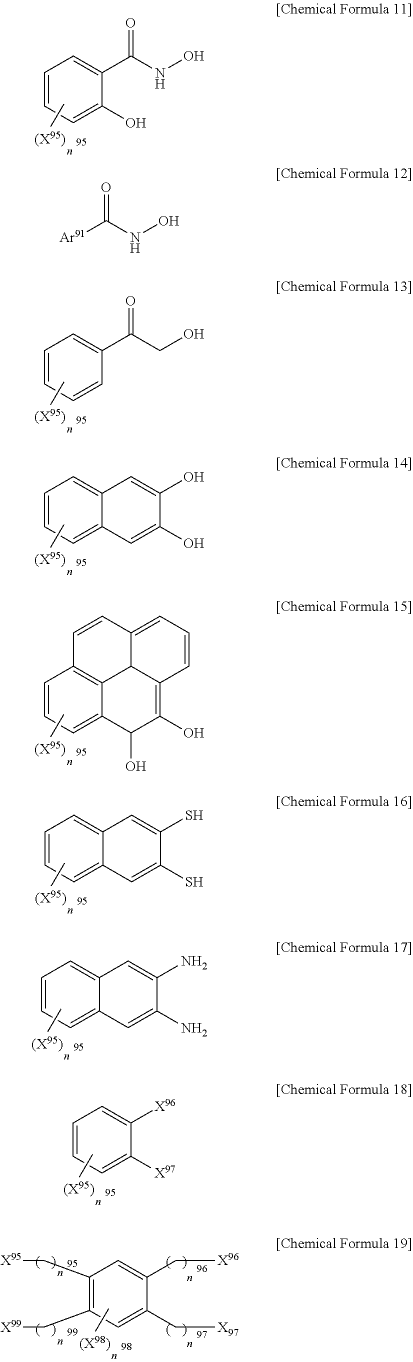 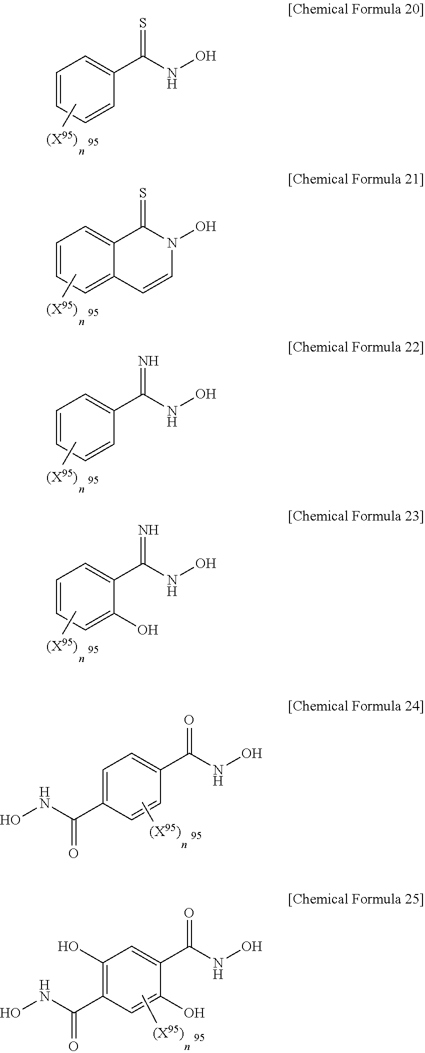
wherein, in Chemical Formulas 11 to 25,
Ar⁹¹ is an aryl group, a heteroaryl group, or any combination thereof,
X⁹⁶ and X⁹⁹ are each independently a substituent including OH, OR′, SH, SR′, or NR′,
R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof,
X⁹⁵ is a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, and
n⁹⁵ is a number of substitutable positions of the aromatic ring in which X⁹⁵ is substituted,
n⁹⁶ to n⁹⁹ are each independently an integer of 1 to 8.

17. The photoresist composition of claim 1, wherein
the photoresist composition includes the organometallic compound in an amount of about 1 wt % to about 30 wt % based on the total weight of the photoresist composition.

18. The photoresist composition of claim 1, wherein
the solvent is selected from aromatic compounds, alcohols, ethers, esters, ketones, naphtha, or a mixture thereof.

19. A photoresist composition, comprising
an organometallic compound represented by Chemical Formula 1; and
a solvent 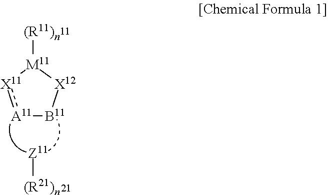
wherein, in Chemical Formula 1,
M¹¹ is a metal selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
X¹¹ and X¹² are each independently selected from O, S, or NR′,
A¹¹ and B¹¹ are each independently a linking group including a single bond, double bond, alkylene group, O, S, NR′, NHC(═O), SO, SO₂, CO, O—CO—O, C(═O)O, OCO, or any combination thereof,
Z¹¹ is an aromatic ring substituted for A¹¹, or Z¹¹ is a linking group including a single bond, double bond, alkylene group, O, S, NR′, NHC(═O), SO, SO₂, CO, O—CO—O, C(═O)O, OCO, or any combination thereof that together with A¹¹ and B¹¹ form an aromatic ring,
R¹¹ and R²¹ are each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof, or R¹¹ is a solvent coordinated to M¹¹, or R¹¹ and R²¹ are each independently a linking group including a single bond, a double bond, an alkylene group, O, S, NR′, NHC(═O), SO, SO₂, CO, O—CO—O, C(═O)O, OCO, or any combination thereof,
R′ is each independently a substituent including a hydrogen, a hydroxy group, a halogen, alkyl group, an alkoxy group, a thiol group, an amine group, a cycloalkyl group, an alkenyl group, a cycloalkenyl group, an alkynyl group, a cycloalkynyl group, an aryl group, a heteroaryl group, or any combination thereof,
n¹¹ is a number of substitutable positions of M¹¹, and
n²¹ is a number of substitutable positions of the aromatic ring.

20. A method of forming patterns, the method comprising:
forming a film to be etched on a substrate;
forming a photoresist film by applying the photoresist composition of claim 1 on the film to be etched;
patterning the photoresist film to form a photoresist pattern; and
etching the film to be etched using the photoresist pattern as an etching mask.
